(19) United States
(12) Patent Application Publication
(10) Pub. No.: US 2026/0317352 A1
(43) Pub. Date: Oct. 15, 2026

(54) ORGANOMETALLIC Sn OXO CARBOXYLATE CLUSTERS WITH CARBOXYLATE LIGANDS THAT CONTAIN A LINEAR OR CYCLIC ESTER FUNCTIONALITY

(71) Applicant: Merck Patent GmbH, Darmstadt (DE)

(72) Inventors: Niels Lichtenberger, Darmstadt (DE); Daniel Hudson, Langen (DE); Philipp Hans Fackler, Rossdorf (DE)

(21) Appl. No.: 19/585,919

(22) PCT Filed: Nov. 6, 2024
(86) PCT No.: PCT/EP2024/081298

§ 371 Date: May 8, 2026

Related U.S. Application Data
(60) Provisional application No. 63/597,036, filed on Nov. 8, 2023.

(51) Int. Cl. C07F 7/22; G03F 7/004; G03F 7/16

(52) U.S. Cl. CPC C07F 7/2224; G03F 7/0042; G03F 7/162

(57) ABSTRACT

The disclosed and claimed subject matter relates to Sn6-oxo clusters with carboxylic acids containing linear ester or cyclic ester (lactone) functional groups, the synthesis thereof, formulations thereof and use thereof in EUV lithography.

### BACKGROUND

### Field

The disclosed and claimed subject matter relates to Sn6-oxo clusters with carboxylic acids containing linear ester or cyclic ester (lactone) functional groups, the synthesis thereof, formulations thereof and use thereof in EUV lithography.

### Related Art

The semiconductor industry is currently considering the use of metal-containing materials as EUV photoresist material for patterning. Many organometallic complexes especially tin-containing compounds have been evaluated as potential precursors for the formation of photoresist material via either spin coating or chemical vapor deposition.

Sn compounds/clusters are of interest as photoresists due to their mechanical strength and etch resistivity of the crosslinked material. However, in order to serve as a photoresist, they need to have good photosensitivity and photoresolution.

For example, U.S. Pat. No. 10,787,466 discloses compositions of monoalkyltin trialkoxide compounds of formula RSn(OR′)₃ or monoalkyltin triamide compounds of formula RSn(NR′₂)₃ where (i) R is a hydrocarbyl group with 1-31 carbon atoms, and where R′ is a hydrocarbyl group with 1-10 carbon atoms and (ii) the compositions contain no more than 4 mol % of dialkyltin compounds relative to the total amount of tin. Also disclosed is a composition including a monoalkyl triamidotin compound of formula RSn—(NR′COR″)₃ where R is a hydrocarbyl group with 1-31 carbon atoms, and where R′ and R″ are independently a hydrocarbyl group with 1-10 carbon atoms. It is believed that having the dialkyltin compounds (as impurities) in the formulation affects performance.

WO2019246254 discloses precursor solutions for radiation patternable coatings that are formed with an organic solvent and monoalkyltin trialkoxides in which the water content of the solvent is adjusted to be within 10% of a selected value. Generally, the water content of the solvent is adjusted through the addition of water, although water removal can also be used. For example, in some embodiments, the adjusted water content of the solvent can be from about 250 ppm by wt. to about 10,000 ppm by wt. With the appropriate selection of ligands, the adjusted precursor solutions are asserted to be stable for at least about 42 days, and in some cases at least 8 months.

U.S. Pat. No. 10,732,505 discloses organometallic precursors for the formation of high-resolution lithography patterning coatings based on metal oxide hydroxide chemistry. The precursor compositions generally include ligands that are readily hydrolysable by water vapor or other —OH source under modest conditions. In particular, the organometallic precursors include a radiation sensitive organo ligand to tin that can result in a coating that can be effective for high-resolution patterning at relatively low radiation doses and is particularly useful for EUV patterning.

Sn12 clusters (i.e., [(RSn)₁₂O₁₄(OH)₆]X₂) have been described as being photosensitive in EUV and eBeam exposures. See Sharps et al., Chem. Mater., 31, 4840-4850 (2019); U.S. Pat. No. 9,310,684; Castellanos et al., Appl. Mat. Int., 12, 9881-9889 (2020); and Herman et al., Appl. Mat. Int., 11, 4514-4522 (2019). The changes in the material, coated on a wafer as a photosensitive layer, have been investigated and several hypotheses on how a solubility contrast is induced by exposure to ionizing radiation were discussed. See Castellanos et al., Appl. Mat. Int., 12, 9881-9889 (2020) and Herman et al., Appl. Mat. Int., 11, 4514-4522 (2019).

Sn6 drum clusters may provide attractive alternatives compared to known Sn-based systems due to their high stability, which is expected to result in a stable formulation as well as a stable photoresist film. Sn6 drum clusters include a Sn₆O₆ core. This core motif is built up from six (Sn₂O₂) four-membered rings that are fused along their edges into a cyclic structure that resembles a drum. Alternatively, the Sn₆O₆ core can be described as two (Sn₃O₃) rings with Sn—O—Sn linkages. The two rings are aligned so that a drum-like motif is formed and rotated with respect to each other, as an effect of additional Sn—O-bridges between the rings. Each Sn atom is covalently bound to one organic substituent R^{Sn}, typically alkyl or aryl groups. In addition, carboxylate ligands R^{ac}CO²⁻ are present that are bound in a bridging fashion. They form links between two tin atoms from the six-membered rings. This arrangement leads to a specific orientation of the different ligands. The R^{Sn}-groups are all located on the six-membered rings and the carboxylate residues point outwards from the radial part of the cluster core. For example, (nBuSn)₆O₆(O₂CCH₃)₆ has the following structure (H atoms not drawn), see Reuter et al., Acta Cryst. (2013), E69, m4:

Various functionalized Sn6 cluster derivatives have been synthesized and applied for various applications like material science or medicinal chemistry. See Holmes et al., Inorganic Chemistry, 24, 13, 1970 (1985); Chandrasekhar et al., Inorganica Chimica Acta, 522, 120378 (2021), Chandrasekhar et al., Inorg. Chem., 24, 1970-71 (1987) and Xiao et al., Journal of Molecular Structure, 1190, 116 (2019). Notably, such clusters in which the carboxylic acid ligands contain a linear ester or cyclic ester (lactone) functionality have not been reported. This is likely explained by the fact that Sn compounds are known to be good esterification catalysts, which can lead to unintended side reactions during the cluster formation.

One paper describes a group of Sn6 acetate clusters [(R^{a}Sn)₆O₆(O₂CCH₃)₆] where the alkyl chain R^{a} bound to the Sn atoms contains an ester function (R^{a}═—(CH₂)ₙ—CO₂R or —(CH₂)ₙ—OC(O)R). These clusters are prepared from the trisalkinyl Sn compounds R^{a}Sn(C≡C—R′) via reaction with water and acetic acid. See Jaumier, Jousseaume, Main Gr. Met. Chem., 325-329 (1998). The access to the R^{a}Sn(C≡C—R′) (respectively R^{a}SnCl₃) starting materials is synthetically limited and involves a multi-step synthesis. See Jousseaume et al., Organometallics, 14, 685-689 (1995). Hence, the use of these compounds does not allow for an easy modification of the organic cluster backbone. In contrast, the use of carboxylic acids for the introduction of ester functional groups into the cluster provides a simple, variable method for such a modification to alter the material properties.

There has, however, been only very limited research into the use of Sn6 clusters as EUV resists. For example, Sharps et al. mentioned the potential use of Sn6 drum-cluster type system as EUV resist. In particular, they studied the crystal density and intermolecular distances of non-functionalized drum cluster systems. See Sharps et al., Cryst. Res. Technol., 52, 1700081 (2017). This same group further explored the use of one Sn6-drum cluster—(nBuSn)₆O₆(O₂CCH₃)₆(“Sn6-nBu-OAc”)—for the use in e-beam lithography. Here only dose curves have been described and it was stated that this Sn6-cluster exhibited much lower sensitivity than a comparable Sn12 cluster. See Sharps et al., Chem. Mater., 31, 4840-4850 (2019).

U.S. Patent Application Publication No. 2021/0087210 discloses a very specific set of Sn6 clusters for use as photoresists but without supporting application data. The disclosed materials are all nBuSn Sn6 clusters that include different carboxylate groups. All of the carboxylic acids described in this patent application are based on aromatic groups that are very rigid and thus are expected to show poor crosslinking capabilities. In contrast, the carboxylate ligands described herein are (partially) based on aliphatic units that provide more flexibility for crosslinking processes.

U.S. Patent Application Publication No. 2023/0384667 discloses a set of Sn6 drum cluster molecules and with saturated or unsaturated groups bound to the Sn atoms as well as the carboxylate groups. The application describes groups that can contain hydroxy-groups, ethers, (substituted) amines, sulfonyl groups, thiol groups, ketones or aldehydes. Notably, linear or cyclic esters are not described or claimed. As shown in the examples and comparative examples, the presence of such ester groups is beneficial for the photoresist properties and performance. Based on the experimental results, the synthesis of ester and lactone containing Sn6 clusters is not possible via the synthesis route described in the application due to undesirable side reactions.

U.S. Patent Application Publication No. 2024/0112912 discloses the use of Sn cluster compounds as additives that serve as EUV sensitizer molecules to a Zr or Hf oxo cluster resist formulations. Sn6 drum clusters are also generally described as an additional/supplemental component in the Zr or Hf oxo cluster resist formulations. The Sn6 drum clusters described in the application contain nBu-Sn groups and are limited to a narrow set of saturated or unsaturated aliphatic groups in the backbone of the carboxylate ligands (i.e., the R-group of the carboxylate). In addition to providing no guidance or examples of how to synthesize these compounds, the described R-groups of the carboxylate ligands do not contain any heteroatoms in the backbone and hence also do not contain esters or lactones as functional groups. In this regard, and as shown in the examples and comparative examples, the presence of ester groups in the carboxylate backbone is beneficial for the photoresist properties and performance.

U.S. Patent Application Publication No. 2024/0168373 discloses a composition of comprising a photosensitive Sn6-oxo cluster or Sn12-oxo cluster and a second photosensitive material which is different from the first photosensitive material. The Sn6-oxo cluster can be substituted with methyl, n-butyl, vinyl, or allyl groups and comprises carboxylic acids having hydrocarbon residues. None of the disclosed residues contains a heteroatom, and therefore also no functional group, aside from an unsaturated C—C bond. As shown in the examples and comparative examples, the presence of ester groups in the carboxylate backbone is beneficial for the photoresist properties and performance.

Here, Sn6 drum clusters with carboxylate ligands that contain at least one linear ester or cyclic ester (lactone) in the backbone are disclosed and claimed. Specific examples of such include, but are not limited to, those derived from the following carboxylic acids:

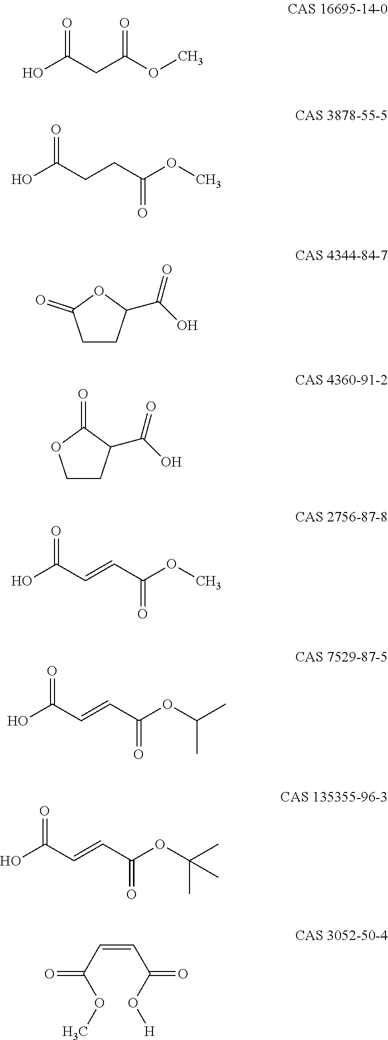

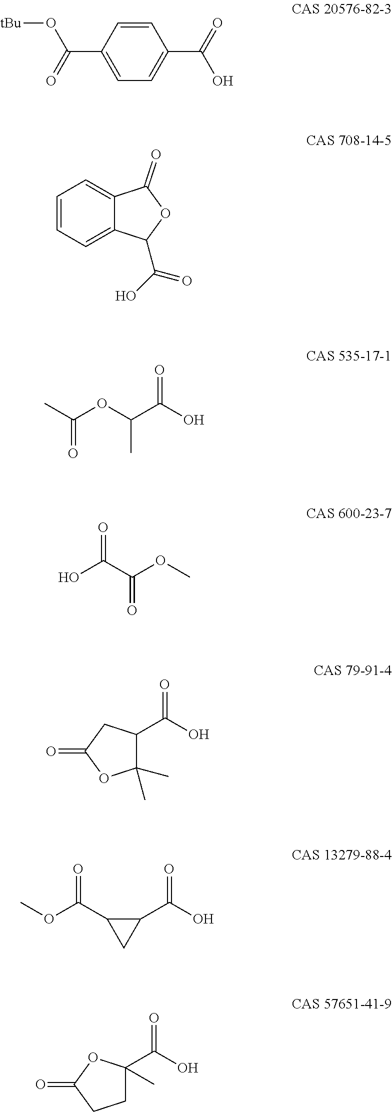

The functional group can be located directly in alpha position to the carboxylate group or connected to it via a bridging carbon chain, ring system, or a combination thereof.

Without being bound by theory it is believed that organic esters can be cleaved during EUV exposure and optional subsequent baking steps, generating free additional carboxylic acid groups in the film, which will increase the crosslinking density between cluster molecules. Sn6 drum clusters containing organic esters in the carboxylate backbone are therefore interesting materials, as an increase in photospeed and a good network formation in the film after exposure and processing can be expected.

The synthesis of these compounds could only be achieved by switching the synthesis route from the most common method of water removal from a mixture of a stannoic acid and carboxylic acid in refluxing toluene or with molecular sieves to a cluster interconversion. This procedure is performed under mild conditions at room temperature, which sufficiently reduces the side reactions that are likely to occur when organic esters and alkyl Sn compounds are present in the same solution.

### SUMMARY

In one embodiment the disclosed and claimed subject matter relates to Sn6-oxo clusters with linear ester or cyclic ester (lactone) functional groups of the formula:

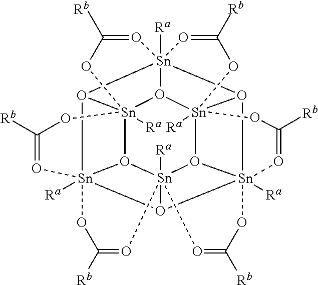

(hereinafter “[(R^{a}Sn)₆O₆(O₂C—R^{b})₆]”)
where
(A) R^{a} is selected from the group of an unsubstituted linear C₁-C₁₀ alkyl group, a linear C₁-C₆ alkyl group substituted with a halogen, a linear C₁-C₆ alkyl group substituted with an amino group, a linear C₁-C₆ alkyl group substituted with a C₅-C₆ unsubstituted aromatic group, an unsubstituted branched C₃-C₁₀ alkyl group, a branched C₃-C₁₀ alkyl group substituted with a halogen, a C₁-C₁₀ heteroalkylene, a branched C₃-C₁₀ alkyl group substituted with an unsubstituted amine, a substituted amine, —Si(CH₃)₃, a benzyl group, a C₃-C₈ unsubstituted cyclic alkyl group, a C₃-C₈ cyclic alkyl group substituted with a halogen, a C₃-C₈ cyclic alkyl group substituted with an amino group, a C₄-C₈ unsubstituted aromatic group, a C₄-C₈ aromatic group substituted with a halogen, a C₄-C₈ aromatic group substituted with an amino group, a C₃-C₁₀ heterocyclic group, a C₂-C₁₀ alkenyl group and a C₃-C₁₀ alkynyl group; and
(B) R^{b} is a selected from the group of
   (i) formula (1):

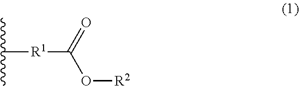

where R¹ is (i) a direct covalent bond or (ii) an unsubstituted linear C₁-C₆ alkylene group, an unsubstituted branched C₃-C₆ alkylene group, an unsubstituted linear C₂-C₆ alkenylene group, an unsubstituted branched C₃-C₆ alkenylene group, an unsubstituted linear C₂-C₆ alkynylene group, an unsubstituted branched C₄-C₆ alkynylene group, a C₃-C₈ unsubstituted cyclic alkylene group, or an unsubstituted C₆ aryl group; and
where R² is an unsubstituted linear C₁-C₆ alkyl group, an unsubstituted branched C₃-C₆ alkyl group, an unsubstituted linear C₂-C₆ alkenyl group, an unsubstituted branched C₃-C₆ alkenyl group, an unsubstituted linear C₂-C₆ alkynyl group, an unsubstituted branched C₄-C₆ alkynyl group, a C₃-C₈ unsubstituted cyclic alkyl group, or an unsubstituted C₆ aryl group;
(ii) formula (2):

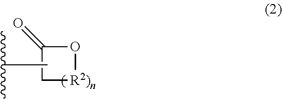

where (i) n=1-5, (ii) each R² is individually one of an oxygen, an unsubstituted methylene group or a methylene group substituted with one or two C₁-C₄ alkyl groups and (iii) formula (2) is free of peroxide groups;
(iii) formula (3):

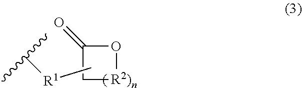

where (i) R¹ is an unsubstituted linear C₁-C₆ alkylene group, an unsubstituted branched C₃-C₆ alkylene group, an unsubstituted linear C₂-C₆ alkenylene group, an unsubstituted branched C₃-C₆ alkenylene group, an unsubstituted linear C₂-C₆ alkynylene group, an unsubstituted branched C₄-C₆ alkynylene group or a C₃-C₈ unsubstituted cyclic alkylene group, (ii) n=1-5, (iii) each R² is individually one of an oxygen, an unsubstituted methylene group or a methylene group substituted with one or two C₁-C₄ alkyl groups and (iv) formula (3) is free of peroxide groups;
(iv) formula (4):

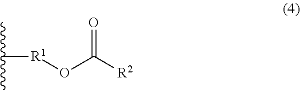

where (i) each R¹ is independently an unsubstituted linear C₁-C₆ alkylene group, an unsubstituted branched C₃-C₆ alkylene group, an unsubstituted linear C₂-C₆ alkenylene group, an unsubstituted branched C₃-C₆ alkenylene group, an unsubstituted linear C₂-C₆ alkynylene group, an unsubstituted branched C₄-C₆ alkynylene group or a C₃-C₈ unsubstituted cyclic alkylene group and (ii) each R² is independently an unsubstituted linear C₁-C₆ alkyl group, an unsubstituted branched C₃-C₆ alkyl group, an unsubstituted linear C₂-C₆ alkenyl group, an unsubstituted branched C₃-C₆ alkenyl group, an unsubstituted linear C₂-C₆ alkynyl group, an unsubstituted branched C₄-C₆ alkynyl group or a C₃-C₈ unsubstituted cyclic alkyl group;
(v) formulae (5):

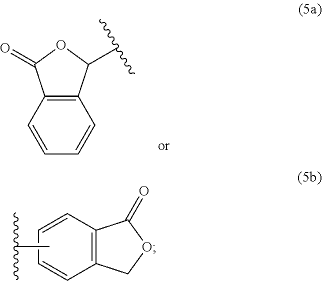

(vi) formulae (6):

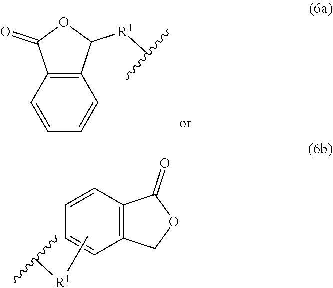

where R¹ is an unsubstituted linear C₁-C₆ alkylene group, an unsubstituted branched C₃-C₆ alkylene group, an unsubstituted linear C₂-C₆ alkenylene group, an unsubstituted branched C₃-C₆ alkenylene group, an unsubstituted linear C₂-C₆ alkynylene group, an unsubstituted branched C₄-C₆ alkynylene group; or
(vii) formulae (7):

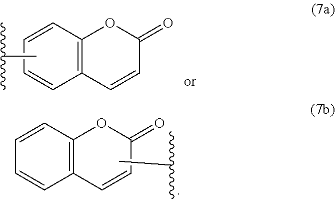

In another aspect, the disclosed and claimed subject matter includes using the Sn6-oxo clusters of the disclosed and claimed subject matter in or to prepare formulations that are useful in EUV processes. Such formulations are or can be used for patterning a radiation sensitive coating in a process that includes (i) forming a coating on a substrate surface with a precursor solution where the precursor solution is prepared from the Sn6-oxo clusters described herein and/or utilized the process for preparing the same, (ii) drying the coating; and (iii) irradiating the dried coating to form a latent image.

In another aspect, the disclosed and claimed subject matter includes methods for preparing the Sn6-oxo clusters described herein.

This summary section does not specify every embodiment and/or incrementally novel aspect of the disclosed and claimed subject matter. Instead, this summary only provides a preliminary discussion of different embodiments and corresponding points of novelty over conventional techniques and the known art. For additional details and/or possible perspectives of the disclosed and claimed subject matter and embodiments, the reader is directed to the Detailed Description section and corresponding figures of the disclosure as further discussed below.

The order of discussion of the different steps described herein has been presented for clarity's sake. In general, the steps disclosed herein can be performed in any suitable order. Additionally, although each of the different features, techniques, configurations, etc. disclosed herein may be discussed in different places of this disclosure, it is intended that each of the concepts can be executed independently of each other or in combination with each other as appropriate. Accordingly, the disclosed and claimed subject matter can be embodied and viewed in many different ways.

### Definitions

Unless otherwise stated, the following terms used in the specification and claims shall have the following meanings for this application.

In this application, the use of the singular includes the plural, and the words “a,” “an” and “the” mean “at least one” unless specifically stated otherwise. Furthermore, the use of the term “including,” as well as other forms such as “includes” and “included,” is not limiting. Also, terms such as “element” or “component” encompass both elements or components including one unit and elements or components that include more than one unit, unless specifically stated otherwise. As used herein, the conjunction “and” is intended to be inclusive and the conjunction “of” is not intended to be exclusive, unless otherwise indicated. For example, the phrase “or, alternatively” is intended to be exclusive. As used herein, the term “and/of” refers to any combination of the foregoing elements including using a single element.

The term “about” or “approximately,” when used in connection with a measurable numerical variable, refers to the indicated value of the variable and to all values of the variable that are within the experimental error of the indicated value (e.g., within the 95% confidence limit for the mean) or within percentage of the indicated value (e.g., ±10%, ±5%), whichever is greater.

As used herein, “C_{x-y}” (where x and y are each independently integers) designates the number of carbon atoms in a chain. For example, C₁₋₆ alkyl refers to an alkyl chain having a chain of between 1 and 6 carbons (e.g., methyl, ethyl, propyl, butyl, pentyl and hexyl). Unless specifically stated otherwise, the chain can be linear or branched.

Unless otherwise indicated, “alkyl” refers to hydrocarbon groups which can be linear, branched (e.g., methyl, ethyl, propyl, isopropyl, tert-butyl and the like), cyclic (e.g., cyclohexyl, cyclopropyl, cyclopentyl and the like) or multicyclic (e.g., norbornyl, adamantly and the like). Suitable acyclic groups can be methyl, ethyl, n- or iso-propyl, n-, iso, or tert-butyl, linear or branched pentyl, hexyl, heptyl, octyl, decyl, dodecyl, tetradecyl and hexadecyl. Unless otherwise stated, alkyl refers to 1-10 carbon atom moieties. The cyclic alkyl groups may be mono cyclic or polycyclic. Suitable examples of mono-cyclic alkyl groups include substituted cyclopentyl, cyclohexyl, and cycloheptyl groups. As mentioned herein the cyclic alkyl groups may have any of the acyclic alkyl groups as substituent. These alkyl moieties may be substituted or unsubstituted.

“Halogenated alkyl” refers to a linear, cyclic or branched saturated alkyl group as defined above in which one or more of the hydrogens has been replaced by a halogen (e.g., F, Cl, Br and I). Thus, for example, a fluorinated alkyl (a.k.a. “fluoroalkyl”) refers to a linear, cyclic or branched saturated alkyl group as defined above in which one or more of the hydrogens has been replaced by fluorine (e.g., trifluoromethyl, pefluoroethyl, 2,2,2-trifluoroethyl, prefluoroisopropyl, perfluorocyclohexyl and the like). Such haloalkyl moieties (e.g., fluoroalkyl moieties), if not perhalogenated/multihalogentated, may be unsubstituted or further substituted.

“Alkenyl” refers to monovalent hydrocarbon groups comprising at least one carbon-carbon double bond wherein the alkenyl group can be linear, branched (e.g., ethenyl, propenyl, isopropenyl, butenyl, isobutenyl and the like), monocyclic (e.g., cyclobutenyl, cyclopentenyl, cyclohexenyl and the like) or multicyclic. Unless otherwise stated, alkenyl refers to 2-10 carbon atom moieties. These alkenyl moieties may be substituted, if indicated accordingly, or unsubstituted.

“Alkynyl” refers to monovalent hydrocarbon groups comprising at least one carbon-carbon triple bond wherein the alkynyl group can be linear (e.g. ethinyl, propinyl, butinyl and the like), branched, monocyclic or multicyclic. Unless otherwise stated, alkynyl refers to 2-10 carbon atom moieties. These alkynyl moieties may be substituted, if indicated accordingly, or unsubstituted.

“Alkoxy” (a.k.a. “alkyloxy”) refers to an alkyl group as defined above which is attached through an oxy (—O—) moiety (e.g., methoxy, ethoxy, propoxy, butoxy, 1,2-isopropoxy, cyclopentyloxy, cyclohexyloxy and the like). These alkoxy moieties may be substituted or unsubstituted.

“Alkyl carbonyl” refers to an alkyl group as defined above which is attached through a carbonyl group (—C(═O—)) moiety (e.g., methylcarbonyl, ethylcarbonyl, propylcarbonyl, buttylcarbonyl, cyclopentylcarbonyl and the like). These alkyl carbonyl moieties may be substituted or unsubstituted.

“Halo” or “halide” refers to a halogen (e.g., F, Cl, Br and I).

“Hydroxy” (a.k.a. “hydroxyl”) refers to an —OH group.

The term “aryl” denotes an aromatic cyclic functional group having from 4 to 10 carbon atoms, from 5 to 10 carbon atoms, or from 6 to 10 carbon atoms. Exemplary aryl groups include, but are not limited to, phenyl, 1-phenylethyl (Ph(Me)CH—), 1-phenyl-1-methyl-ethyl (Ph(Me)₂C—), benzyl, chlorobenzyl, tolyl, o-xylyl, 1,2,3-triazolyl, pyrrolyl, and furanyl.

In addition to known and understood representations for the attachment point of a covalent bond, the notation

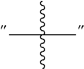

is intended to also designate the attachment point of a covalent bond.

“Alkylene” means a linear saturated divalent hydrocarbon radical of one or more carbon atoms or a branched saturated divalent hydrocarbon radical of three to six carbon atoms unless otherwise stated (e.g., methylene, ethylene, propylene, 1-methylpropylene, 2-methylpropylene, butylene, pentylene, and the like) serving as a linkage between other chemical groups in the disclosed and claimed compounds (such as an ethylene bridge). Specific examples of the alkylene linkages include methylene (—CH₂—), ethylene (—CH₂CH₂—), substituted ethylenes, (e.g., —CH(CH₃)CH₂—; —CH(CH₃)CH(CH₃)—; —C(CH₃)₂CH₂—), propylene (—CH₂CH₂CH₂—) and substituted propylenes.

“Alkenylene” means a linear unsaturated divalent hydrocarbon radical of two or more carbon atoms or a branched divalent hydrocarbon radical of three to six carbon atoms containing at least one double bond between two Carbon atoms unless otherwise stated (e.g., ethenylene, propenylene, 1-methylpropenylene, 2-methylpropenylene, butenylene, pentenylene, and the like). Specific examples of the alkenylene linkages include ethenylene (—CH═CH—), substituted ethenylenes, (e.g., —(CH₃)C═CH—; —(CH₃)C═C(CH₃)—), propenylene (—CH═CHCH₂—) and substituted propenylenes.

“Alkynylene” means a linear unsaturated divalent hydrocarbon radical of two or more carbon atoms or a branched unsaturated divalent hydrocarbon radical of four to six carbon atoms containing at least one triple bond between two Carbon atoms unless otherwise stated (e.g., ethynylene, propynylene, 3-methylpropynylene, butynylene, pentynylene, and the like). Specific examples of the alkynylene linkages include ethynylene (—C≡C—), propynylene (—C≡CCH₂—) and substituted propynylenes.

“Heteroalkylene” means an -(alkylene)- radical as defined above where one, two or three carbons in the alkylene chain is replaced by —O—, N(H, alkyl, or substituted alkyl), S, SO, SO2, or CO. In some preferred embodiments, the carbons are replaced by O or N.

A “peroxide group” is a “—O—O—” moiety. Groups having sequentially bonded oxygens (e.g., —O—O—O—; —O—O—O—O—, etc.) should be understood to include a peroxide group.

Unless otherwise indicated, the term “substituted” when referring to an alkyl, alkoxy, fluorinated alkyl and the like refers to one of these moieties which also contains one or more substituents including, but not limited, to the following substituents: alkyl, substituted alkyl, unsubstituted aryl, substituted aryl, alkyloxy, alkylaryl, haloalkyl, halide, hydroxy, amino and amino alkyl. Similarly, the term “unsubstituted” refers to these same moieties where no substituents apart from hydrogen are present.

The section headings used herein are for organizational purposes and are not to be construed as limiting the subject matter described. All documents, or portions of documents, cited in this application, including, but not limited to, patents, patent applications, articles, books, and treatises, are hereby expressly incorporated herein by reference in their entirety for any purpose. In the event that any of the incorporated literature and similar materials defines a term in a manner that contradicts the definition of that term in this application, this application controls.

### DETAILED DESCRIPTION

It is to be understood that both the foregoing general description and the following detailed description are illustrative and explanatory, and are not restrictive of the subject matter, as claimed. The objects, features, advantages, and ideas of the disclosed subject matter will be apparent to those skilled in the art from the description provided in the specification, and the disclosed subject matter will be readily practicable by those skilled in the art on the basis of the description appearing herein. The description of any “preferred embodiments” and/or the examples which show preferred modes for practicing the disclosed subject matter are included for the purpose of explanation and are not intended to limit the scope of the claims.

### Sn6-Oxo Clusters

As set forth above, the disclosed and claimed subject matter relates to Sn6-oxo clusters with linear ester or cyclic ester (lactone) functional groups of the formula:

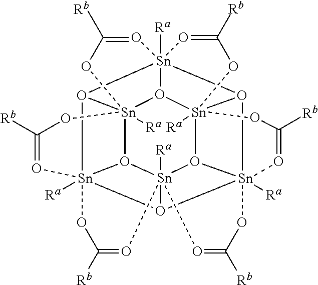

(hereinafter “[(R^{a}Sn)₆O₆(O₂C—R^{b})₆]”)
where
(A) R^{a} is selected from the group of an unsubstituted linear C₁-C₁₀ alkyl group, a linear C₁-C₆ alkyl group substituted with a halogen, a linear C₁-C₆ alkyl group substituted with an amino group, a linear C₁-C₆ alkyl group substituted with a C₅-C₆ unsubstituted aromatic group, an unsubstituted branched C₃-C₁₀ alkyl group, a branched C₃-C₁₀ alkyl group substituted with a halogen, a C₁-C₁₀ heteroalkylene, a branched C₃-C₁₀ alkyl group substituted with an unsubstituted amine, a substituted amine, —Si(CH₃)₃, a benzyl group, a C₃-C₈ unsubstituted cyclic alkyl group, a C₃-C₈ cyclic alkyl group substituted with a halogen, a C₃-C₈ cyclic alkyl group substituted with an amino group, a C₄-C₈ unsubstituted aromatic group, a C₄-C₈ aromatic group substituted with a halogen, a C₄-C₈ aromatic group substituted with an amino group, a C₃-C₁₀ heterocyclic group, a C₂-C₁₀ alkenyl group and a C₃-C₁₀ alkynyl group; and
(B) R^{b} is a selected from the group of
   (i) formula (1):

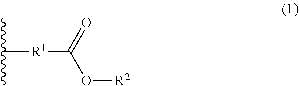

where R¹ is (i) a direct covalent bond or (ii) an unsubstituted linear C₁-C₆ alkylene group, an unsubstituted branched C₃-C₆ alkylene group, an unsubstituted linear C₂-C₆ alkenylene group, an unsubstituted branched C₃-C₆ alkenylene group, an unsubstituted linear C₂-C₆ alkynylene group, an unsubstituted branched C₄-C₆ alkynylene group, a C₃-C₈ unsubstituted cyclic alkylene group, or an unsubstituted C₆ aryl group; and
where R² is an unsubstituted linear C₁-C₆ alkyl group, an unsubstituted branched C₃-C₆ alkyl group, an unsubstituted linear C₂-C₆ alkenyl group, an unsubstituted branched C₃-C₆ alkenyl group, an unsubstituted linear C₂-C₆ alkynyl group, an unsubstituted branched C₄-C₆ alkynyl group, a C₃-C₈ unsubstituted cyclic alkyl group, or an unsubstituted C₆ aryl group;
(ii) formula (2):

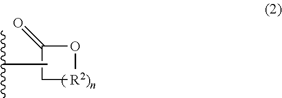

where (i) n=1-5, (ii) each R² is individually one of an oxygen, an unsubstituted methylene group or a methylene group substituted with one or two C₁-C₄ alkyl groups and (iii) formula (2) is free of peroxide groups;
(iii) formula (3):

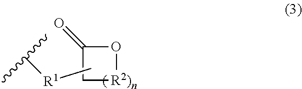

where (i) R¹ is an unsubstituted linear C₁-C₆ alkylene group, an unsubstituted branched C₃-C₆ alkylene group, an unsubstituted linear C₂-C₆ alkenylene group, an unsubstituted branched C₃-C₆ alkenylene group, an unsubstituted linear C₂-C₆ alkynylene group, an unsubstituted branched C₄-C₆ alkynylene group or a C₃-C₈ unsubstituted cyclic alkylene group, (ii) n=1-5 and (iii) each R² is individually one of an oxygen, an unsubstituted methylene group or a methylene group substituted with one or two C₁-C₄ alkyl groups and (iv) formula (3) is free of peroxide groups;
(iv) formula (4):

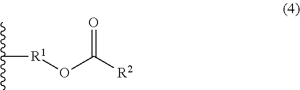

where (i) each R¹ is independently an unsubstituted linear C₁-C₆ alkylene group, an unsubstituted branched C₃-C₆ alkylene group, an unsubstituted linear C₂-C₆ alkenylene group, an unsubstituted branched C₃-C₆ alkenylene group, an unsubstituted linear C₂-C₆ alkynylene group, an unsubstituted branched C₄-C₆ alkynylene group or a C₃-C₈ unsubstituted cyclic alkylene group and (ii) each R² is independently an unsubstituted linear C₁-C₆ alkyl group, an unsubstituted branched C₃-C₆ alkyl group, an unsubstituted linear C₂-C₆ alkenyl group, an unsubstituted branched C₃-C₆ alkenyl group, an unsubstituted linear C₂-C₆ alkynyl group, an unsubstituted branched C₄-C₆ alkynyl group or a C₃-C₈ unsubstituted cyclic alkyl group;
(v) formulae (5):

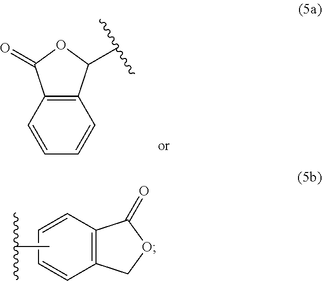

(vi) formulae (6):

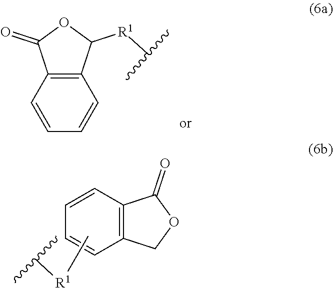

where R¹ is an unsubstituted linear C₁-C₆ alkylene group, an unsubstituted branched C₃-C₆ alkylene group, an unsubstituted linear C₂-C₆ alkenylene group, an unsubstituted branched C₃-C₆ alkenylene group, an unsubstituted linear C₂-C₆ alkynylene group, an unsubstituted branched C₄-C₆ alkynylene group; or
(vii) formulae (7):

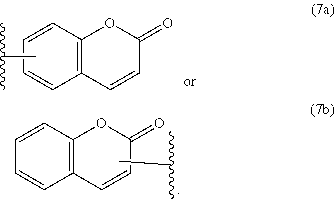

### R^{a} Groups

In one embodiment, R^{a} is selected from the group of an unsubstituted linear C₁-C₄ alkyl group, an unsubstituted branched C₃-C₄ alkyl group, a C₂-C₆ alkenyl group and a C₅-C₆ unsubstituted aromatic group.

In a further aspect of this embodiment, R^{a} is selected from the group of a —CH₃ group, a —CH₂CH₃ group, a —CH(CH₃)₂ group, a —C(CH₃)₃ group, a —CH═CH₂ group, a —CH₂CH═CH₂ group, a —CH₂CH₂CH═CH₂ group, a —CH₂CH₂CH₂CH₃ group, a —C₆Hₛ group and a —CH₂—C₆H₅ group.

In a further aspect of this embodiment, R^{a} is selected from the group of a —CH₃ group, a —CH(CH₃)₂ group, a —C(CH₃)₃ group, a —CH═CH₂ group, a —CH₂CH═CH₂ group, a —CH₂CH₂CH═CH₂ group and a —CH₂CH₂CH₂CH₃ group.

In a further aspect of this embodiment, R^{a} is selected from the group of a —CH₃ group, a —CH(CH₃)₂ group, a —C(CH₃)₃ group and a —CH₂CH₂CH₂CH₃ group.

In a further aspect of this embodiment, R^{a} is selected from the group of a —CH₃ group, a —CH(CH₃)₂ group and a —CH₂CH₂CH₂CH₃ group.

In one aspect of this embodiment, R^{a} is a methyl group. In one aspect of this embodiment, R^{a} is an isopropyl group. In one aspect of this embodiment, R^{a} is a n-butyl group.

### R^{b} Groups

### R^{b}=Formula (1)

In one embodiment, R^{b} is a carboxylic acid moiety of formula (1):

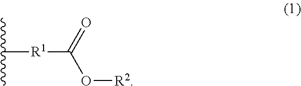

In one aspect of this embodiment, R¹ and R² are the same group. As those skilled in the art will understand, R¹ is considered to be the “same” as R² when R¹ is the corresponding hydrocarbon radical of the R² group. Thus, for example, if R² is a methyl group and R¹ is the “same” then R¹ is a methylene group (i.e., the corresponding hydrocarbon radical group of a methyl group). In one aspect of this embodiment, one R¹ and R² are each a different group.

In one aspect of this embodiment, one or both of R¹ and R² is an unsubstituted linear C₁-C₆ alkyl group. In one aspect of this embodiment, one or both of R¹ and R² is an unsubstituted branched C₃-C₆ alkyl group. In one aspect of this embodiment, one or both of R¹ and R² is an unsubstituted linear C₂-C₆ alkenyl group. In one aspect of this embodiment, one or both of R¹ and R² is an unsubstituted branched C₃-C₆ alkenyl group. In one aspect of this embodiment, one or both of R¹ and R² is an unsubstituted linear C₂-C₆ alkynyl group. In one aspect of this embodiment, one or both of R¹ and R² is an unsubstituted branched C₄-C₆ alkynyl group. In one aspect of this embodiment, one or both of R¹ and R² is a C₃-C₈ unsubstituted cyclic alkyl group. In another aspect of this embodiment, one or both of R¹ and R² is a C₅-C₈ unsubstituted aromatic group. In one aspect of this embodiment, one or both of R¹ and R² is a phenyl group.

In one aspect of this embodiment, R¹ is a direct covalent bond. In one aspect of this embodiment, R¹ is a methylene group. In one aspect of this embodiment, R¹ is an ethylene group. In one aspect of this embodiment, R¹ is a n-propylene group. In one aspect of this embodiment, R¹ is an isopropylene group. In one aspect of this embodiment, R¹ is a s-butylene group. In one aspect of this embodiment, R¹ is a n-butylene group. In one aspect of this embodiment, R¹ is an isobutylene group. In one aspect of this embodiment, R¹ is a t-butylene group. In one aspect of this embodiment, R¹ is an ethenyl group. In one aspect of this embodiment, R¹ is a propenyl group. In one aspect of this embodiment, R¹ is a butenyl group. In one aspect of this embodiment, R¹ is a phenyl group.

In one aspect of this embodiment, R² is an unsubstituted linear C₁-C₆ alkyl group. In one aspect of this embodiment, R² is an unsubstituted branched C₃-C₆ alkyl group. In one aspect of this embodiment, R² is a C₃-C₈ unsubstituted cyclic alkyl group. In another aspect of this embodiment, one or both of R² is a C₅-C₈ unsubstituted aromatic group. In one aspect of this embodiment, R² is a phenyl group.

In one aspect of this embodiment, R² is a methyl group. In one aspect of this embodiment, R² is an ethyl group. In one aspect of this embodiment, R² is a n-propyl group. In one aspect of this embodiment, R² is an isopropyl group. In one aspect of this embodiment, R² is a s-butyl group. In one aspect of this embodiment, R² is a n-butyl group. In one aspect of this embodiment, R² is an isobutyl group. In one aspect of this embodiment, R² is a t-butyl group. In one aspect of this embodiment, R² is an allyl group. In one aspect of this embodiment, R² is a phenyl group.

### R^{b}=Formula (2)

In one embodiment, R^{b} is a carboxylic acid moiety of formula (2):

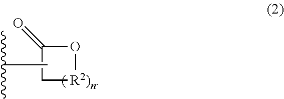

In one aspect of this embodiment, n=1. In one aspect of this embodiment, n=2. In one aspect of this embodiment, n=3. In one aspect of this embodiment, n=4. In one aspect of this embodiment, n=5. In one aspect of this embodiment one or more of the R² is an oxygen. In one aspect of this embodiment one or more of the R² is a methylene group. In one aspect of this embodiment one or more of the R² is a methylene group substituted with one C₁-C₄ alkyl group. In one aspect of this embodiment one or more of the R² is a methylene group substituted with two C₁-C₄ alkyl groups. As noted previously, moieties of formula (2) are free of peroxide groups.

### R^{b}=Formula (3)

In one embodiment, R^{b} is a carboxylic acid moiety of formula (3):

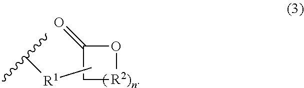

In one aspect of this embodiment, n=1. In one aspect of this embodiment, n=2. In one aspect of this embodiment, n=3. In one aspect of this embodiment, n=4. In one aspect of this embodiment, n=5. In one aspect of this embodiment, R¹ is an unsubstituted linear C₁-C₆ alkylene group. In one aspect of this embodiment, R¹ is an unsubstituted branched C₃-C₆ alkylene group. In one aspect of this embodiment, R¹ is a methylene group. In one aspect of this embodiment, R¹ is an ethylene group. In one aspect of this embodiment, R¹ is a n-propylene group. In one aspect of this embodiment, R¹ is an isopropylene group. In one aspect of this embodiment, R¹ is a s-butylene group. In one aspect of this embodiment, R¹ is a n-butylene group. In one aspect of this embodiment, R¹ is an isobutylene group. In one aspect of this embodiment, R¹ is a t-butylene group. In one aspect of this embodiment, R¹ is an unsubstituted linear C₂-C₆ alkenylene group. In one aspect of this embodiment, R¹ is an unsubstituted branched C₃-C₆ alkenylene group. In one aspect of this embodiment, R¹ is an unsubstituted linear C₂-C₆ alkynylene group. In one aspect of this embodiment, R¹ is an unsubstituted branched C₄-C₆ alkynylene group. In one aspect of this embodiment, R¹ is a C₃-C₈ unsubstituted cyclic alkylene group. In one aspect of this embodiment one or more of the R² is an oxygen. In one aspect of this embodiment one or more of the R² is a methylene group. In one aspect of this embodiment one or more of the R² is a methylene group substituted with one C₁-C₄ alkyl group. In one aspect of this embodiment one or more of the R² is a methylene group substituted with two C₁-C₄ alkyl groups. As noted previously, moieties of formula (3) are free of peroxide groups.

### R^{b}=Formula (4)

In one embodiment, R^{b} is a carboxylic acid moiety of formula (4):

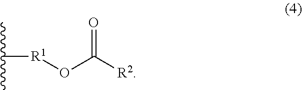

In one aspect of this embodiment, R¹ and R² are the same group. As those skilled in the art will understand, R¹ is considered to be the “same” as R² when R¹ is the corresponding hydrocarbon radical of the R² group. Thus, for example, if R² is a methyl group and R¹ is the “same” then R¹ is a methylene group (i.e., the corresponding hydrocarbon radical group of a methyl group). In one aspect of this embodiment, one R¹ and R² are each a different group.

In one aspect of this embodiment, one or both of R¹ and R² is an unsubstituted linear C₁-C₆ alkyl group. In one aspect of this embodiment, one or both of R¹ and R² is an unsubstituted branched C₃-C₆ alkyl group. In one aspect of this embodiment, one or both of R¹ and R² is an unsubstituted linear C₂-C₆ alkenyl group. In one aspect of this embodiment, one or both of R¹ and R² is an unsubstituted branched C₃-C₆ alkenyl group. In one aspect of this embodiment, one or both of R¹ and R² is an unsubstituted linear C₂-C₆ alkynyl group. In one aspect of this embodiment, one or both of R¹ and R² is an unsubstituted branched C₄-C₆ alkynyl group. In one aspect of this embodiment, one or both of R¹ and R² is a C₃-C₈ unsubstituted cyclic alkyl group.

In one aspect of this embodiment, R¹ is a methylene group. In one aspect of this embodiment, R¹ is an ethylene group. In one aspect of this embodiment, R¹ is a n-propylene group. In one aspect of this embodiment, R¹ is an isopropylene group. In one aspect of this embodiment, R¹ is a s-butylene group. In one aspect of this embodiment, R¹ is a n-butylene group. In one aspect of this embodiment, R¹ is an isobutylene group. In one aspect of this embodiment, R¹ is a t-butylene group.

In one aspect of this embodiment, R² is an unsubstituted linear C₁-C₆ alkyl group. In one aspect of this embodiment, R² is an unsubstituted branched C₃-C₆ alkyl group. In one aspect of this embodiment, R² is an unsubstituted linear C₂-C₆ alkenyl group. In one aspect of this embodiment, R² is an unsubstituted branched C₃-C₆ alkenyl group. In one aspect of this embodiment, R² is a C₃-C₈ unsubstituted cyclic alkyl group. In one aspect of this embodiment, R² is a C₅-C₆ unsubstituted aromatic group.

In one aspect of this embodiment, R² is a methyl group. In one aspect of this embodiment, R² is an ethyl group. In one aspect of this embodiment, R² is a n-propyl group. In one aspect of this embodiment, R² is an isopropyl group. In one aspect of this embodiment, R² is a s-butyl group. In one aspect of this embodiment, R² is a n-butyl group. In one aspect of this embodiment, R² is an isobutyl group. In one aspect of this embodiment, R² is a t-butyl group. In one aspect of this embodiment, R² is an ethenyl group. In one aspect of this embodiment, R² is a propenyl group. In one aspect of this embodiment, R² is an allyl group.

### R^{b}=Formulae (5)

In one embodiment, R^{b} is a carboxylic acid moiety of formulae (5):

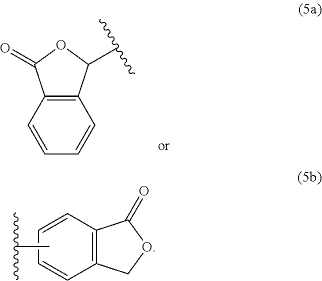

In one aspect of this embodiment, R^{b} is a carboxylic acid moiety of formulae (5a).

In one aspect of this embodiment, R^{b} is a carboxylic acid moiety of formulae (5b).

### R^{b}=Formulae (6)

In one embodiment, R^{b} is a carboxylic acid moiety of formulae (6):

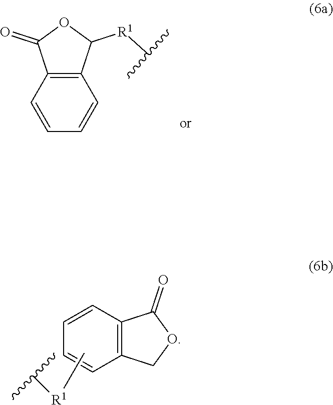

In one aspect of this embodiment, R^{b} is a carboxylic acid moiety of formulae (6a).

In one aspect of this embodiment, R^{b} is a carboxylic acid moiety of formulae (6b).

In one aspect of this embodiment, R¹ is an unsubstituted linear C₁-C₆ alkylene group. In one aspect of this embodiment, R¹ is an unsubstituted branched C₃-C₆ alkylene group. In one aspect of this embodiment, R¹ is a methylene group. In one aspect of this embodiment, R¹ is an ethylene group. In one aspect of this embodiment, R¹ is a n-propylene group. In one aspect of this embodiment, R¹ is an isopropylene group. In one aspect of this embodiment, R¹ is a s-butylene group. In one aspect of this embodiment, R¹ is an n-butylene group. In one aspect of this embodiment, R¹ is an isobutylene group. In one aspect of this embodiment, R¹ is a t-butylene group. In one aspect of this embodiment, R¹ is an unsubstituted linear C₂-C₆ alkenylene group. In one aspect of this embodiment, Ri is an unsubstituted branched C₃-C₆ alkenylene group. In one aspect of this embodiment, R¹ is an unsubstituted linear C₂-C₆ alkynylene group. In one aspect of this embodiment, R is an unsubstituted branched C₄-C₆ alkynylene group.

### R^{b}=Formulae (7)

In one embodiment, R^{b} is a carboxylic acid moiety of formulae (7):

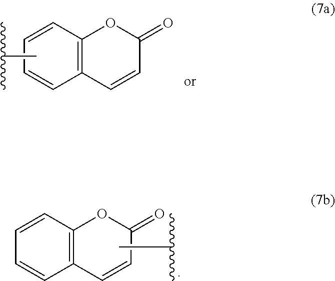

In one aspect of this embodiment, R^{b} is a carboxylic acid moiety of formulae (7a).

In one aspect of this embodiment, R^{b} is a carboxylic acid moiety of formulae (7b).

### Specific R^{b} Carboxylic Acid Moiety Groups

In one aspect of this embodiment, R^{b} is a carboxylic acid moiety group derived from the carboxylic acids exemplified in Table 1. All compounds are drawn without stereochemical information. This embodiment covers the racemic mixtures, mixture with a defined ratio of the stereoisomers as well as the enantiomerically pure compounds. In Table 1, R^{b} is derived from the given carboxylic acids in the way given below:

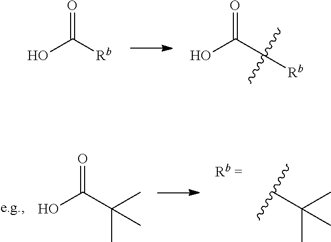

TABLE 1

| | |
|---|---|
| 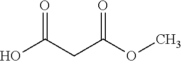 | 1A |
| 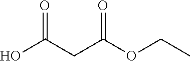 | 2A |
| 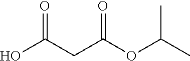 | 3A |
| 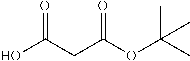 | 4A |
| 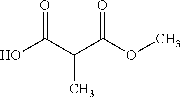 | 5A |
| 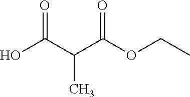 | 6A |
| 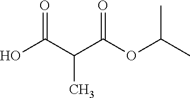 | 7A |
| 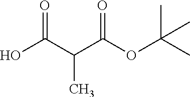 | 8A |
| 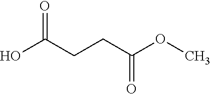 | 9A |
| 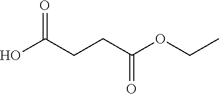 | 10A |
| 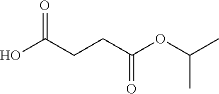 | 11A |
| 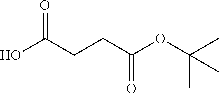 | 12A |
| 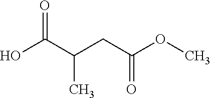 | 13A |
| 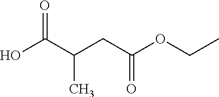 | 14A |
| 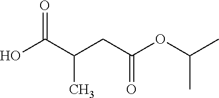 | 15A |
| 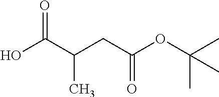 | 16A |
| 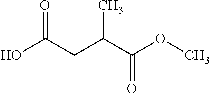 | 17A |
| 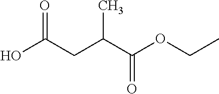 | 18A |
| 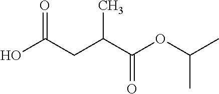 | 19A |
| 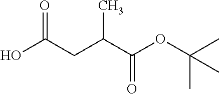 | 20A |
| 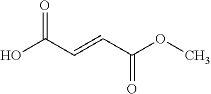 | 21A |
| 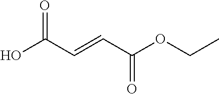 | 22A |
| 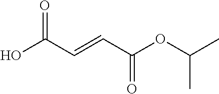 | 23A |
| 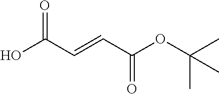 | 24A |
| 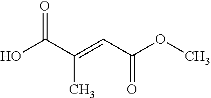 | 25A |
| 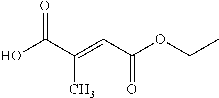 | 26A |
| 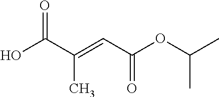 | 27A |
| 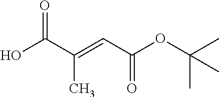 | 28A |
| 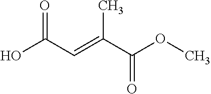 | 29A |
| 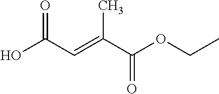 | 30A |
| 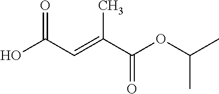 | 31A |
| 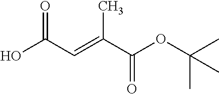 | 32A |
| 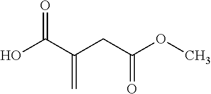 | 33A |
| 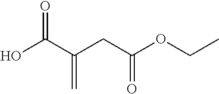 | 34A |
| 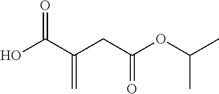 | 35A |
| 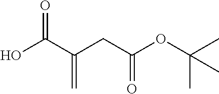 | 36A |
| 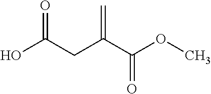 | 37A |
| 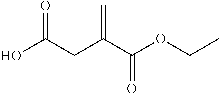 | 38A |
| 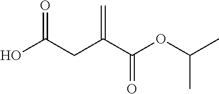 | 39A |
| 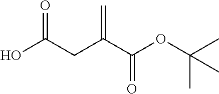 | 40A |
| 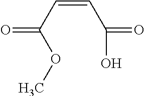 | 41A |
| 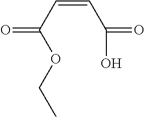 | 42A |
| 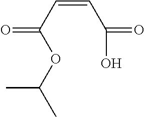 | 43A |
| 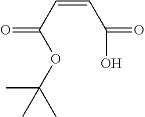 | 44A |
| 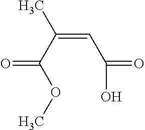 | 45A |
| 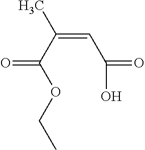 | 46A |
| 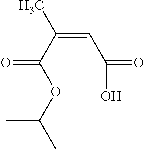 | 47A |
| 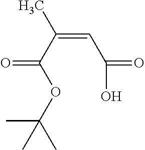 | 48A |
| 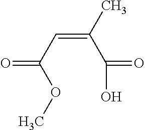 | 49A |
| 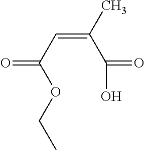 | 50A |
| 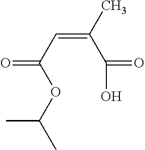 | 51A |
| 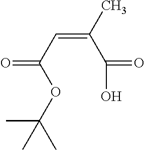 | 52A |
| 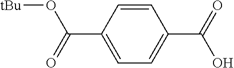 [SMILES: CC(C)(C)OC(=O)c1ccc(C(=O)O)cc1] | 53A |
| 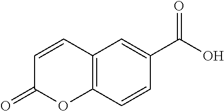 [SMILES: O=C(O)c1ccc2oc(=O)ccc2c1] | 54A |
| 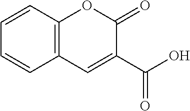 [SMILES: O=C(O)c1cc2ccccc2oc1=O] | 55A |
| 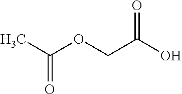 | 56A |
| 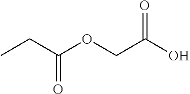 | 57A |
| 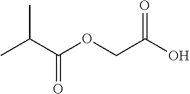 | 58A |
| 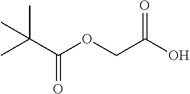 | 59A |
| 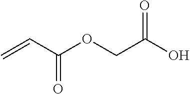 | 60A |
| 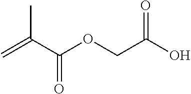 | 61A |
| 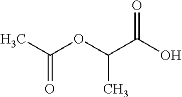 | 62A |
| 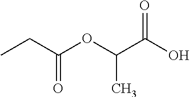 | 63A |
| 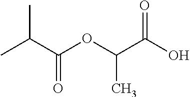 | 64A |
| 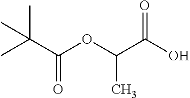 | 65A |
| 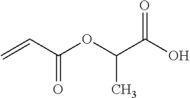 | 66A |
| 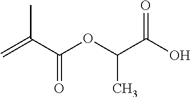 | 67A |
| 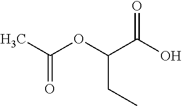 | 68A |
| 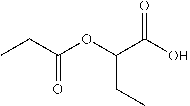 | 69A |
| 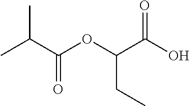 | 70A |
| 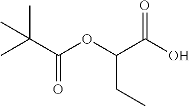 | 71A |
| 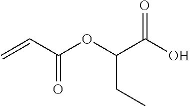 | 72A |
| 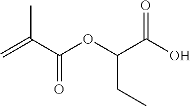 | 73A |
| 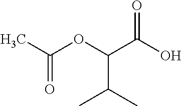 | 74A |
| 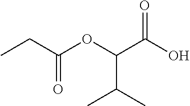 | 75A |
| 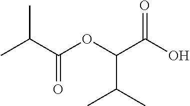 | 76A |
| 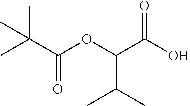 | 77A |
| 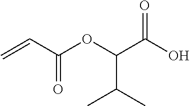 | 78A |
| 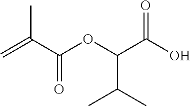 | 79A |
| 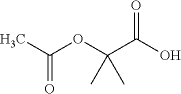 | 80A |
| 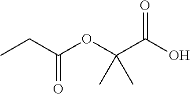 | 81A |
| 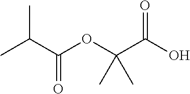 | 82A |
| 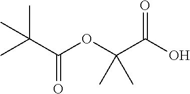 | 83A |
| 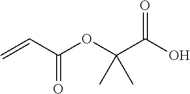 | 84A |
| 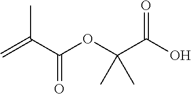 | 85A |
| 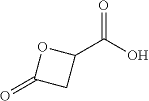 | 86A |
| 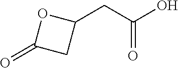 | 87A |
| 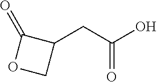 | 88A |
| 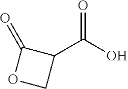 | 89A |
| 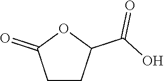 | 90A |
| 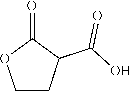 | 91A |
| 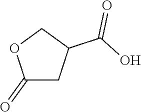 | 92A |
| 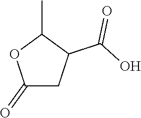 | 93A |
| 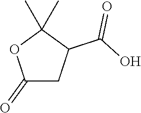 | 94A |
| 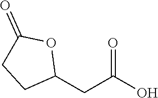 | 95A |
| 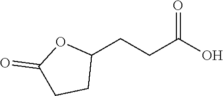 [SMILES: O=C(O)CCC1CCC(=O)O1] | 96A |
| 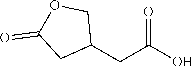 | 97A |
| 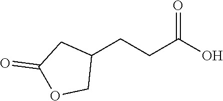 [SMILES: O=C(O)CCC1COC(=O)C1] | 98A |
| 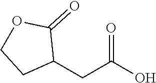 | 99A |
| 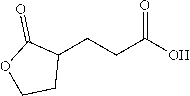 [SMILES: O=C(O)CCC1CCOC1=O] | 100A |
| 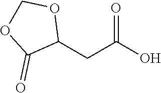 | 101A |
| 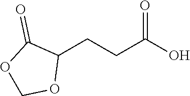 [SMILES: O=C(O)CCC1OCOC1=O] | 102A |
| 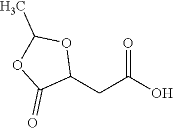 | 103A |
| 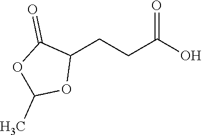 | 104A |
| 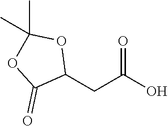 | 105A |
| 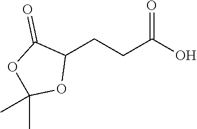 | 106A |
| 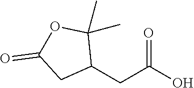 | 107A |
| 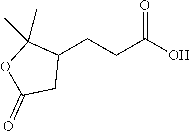 | 108A |
| 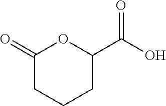 | 109A |
| 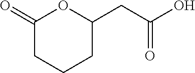 [SMILES: O=C(O)CC1CCCC(=O)O1] | 110A |
| 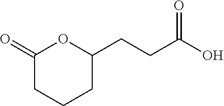 [SMILES: O=C(O)CCC1CCCC(=O)O1] | 111A |
| 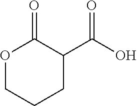 | 112A |
| 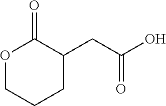 [SMILES: O=C(O)CC1CCCOC1=O] | 113A |
| 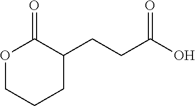 [SMILES: O=C(O)CCC1CCCOC1=O] | 114A |
| 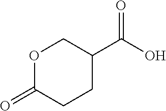 | 115A |
| 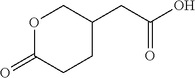 [SMILES: O=C(O)CC1CCC(=O)OC1] | 116A |
| 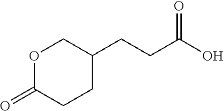 [SMILES: O=C(O)CCC1CCC(=O)OC1] | 117A |
| 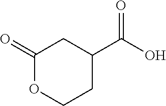 | 118A |
| 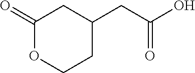 [SMILES: O=C(O)CC1CCOC(=O)C1] | 119A |
| 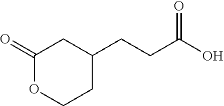 [SMILES: O=C(O)CCC1CCOC(=O)C1] | 120A |
| 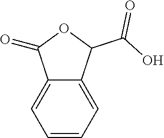 [SMILES: O=C1OC(C(=O)O)c2ccccc21] | 121A |
| 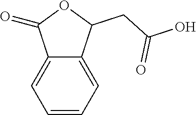 [SMILES: O=C(O)CC1OC(=O)c2ccccc21] | 122A |
| 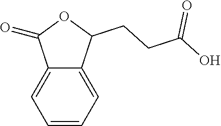 [SMILES: O=C(O)CCC1OC(=O)c2ccccc21] | 123A |
| 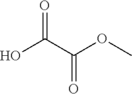 | 124A |
| 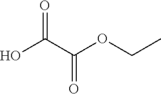 | 125A |
| 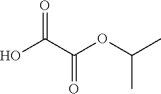 | 126A |
| 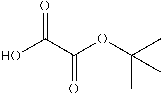 | 127A |
| 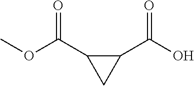 | 128A |
| 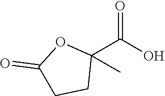 | 129A |

In one aspect of this embodiment, R^{b} is a carboxylic acid moiety group of carboxylic acid 21A.

In one aspect of this embodiment, R^{b} is a carboxylic acid moiety group of carboxylic acid 22A.

In one aspect of this embodiment, R^{b} is a carboxylic acid moiety group of carboxylic acid 23A.

In one aspect of this embodiment, R^{b} is a carboxylic acid moiety group of carboxylic acid 24A.

In one aspect of this embodiment, R^{b} is a carboxylic acid moiety group of carboxylic acid 41A.

In one aspect of this embodiment, R^{b} is a carboxylic acid moiety group of carboxylic acid 42A.

In one aspect of this embodiment, R^{b} is a carboxylic acid moiety group of carboxylic acid 43A.

In one aspect of this embodiment, R^{b} is a carboxylic acid moiety group of carboxylic acid 44A.

In one aspect of this embodiment, R^{b} is a carboxylic acid moiety group of carboxylic acid 62A.

In one aspect of this embodiment, R^{b} is a carboxylic acid moiety group of carboxylic acid 90A.

In one aspect of this embodiment, R^{b} is a carboxylic acid moiety group of carboxylic acid 91A.

In one aspect of this embodiment, R^{b} is a carboxylic acid moiety group of carboxylic acid 92A.

In one aspect of this embodiment, R^{b} is a carboxylic acid moiety group of carboxylic acid 94A.

In one aspect of this embodiment, R^{b} is a carboxylic acid moiety group of carboxylic acid 101A.

In one aspect of this embodiment, R^{b} is a carboxylic acid moiety group of carboxylic acid 103A.

In one aspect of this embodiment, R^{b} is a carboxylic acid moiety group of carboxylic acid 105A.

In one aspect of this embodiment, R^{b} is a carboxylic acid moiety group of carboxylic acid 124A.

In one aspect of this embodiment, R^{b} is a carboxylic acid moiety group of carboxylic acid 128A.

In one aspect of this embodiment, R^{b} is a carboxylic acid moiety group of carboxylic acid 129A.

### Exemplary Sn6-Oxo Clusters

In one aspect, the Sn6-oxo clusters with carboxylic acids moieties containing a lactone or ester functional groups have one or more of the following structures as illustrated in Table 2:

TABLE 2

| | 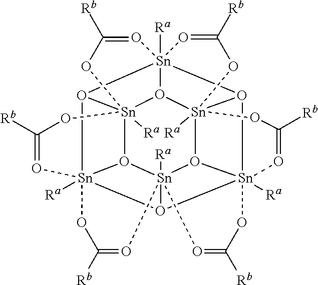 | |
|---|---|---|
| | Cluster Structure | |
| Formula | R^{a} | R^{b} |
| [(MeSn)₆O₆(O₂C—CH₂CO₂Me)₆] | 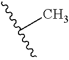 | 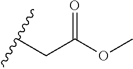 [SMILES: *CC(=O)OC] |
| [(MeSn)₆O₆(O₂C—C₂H₄CO₂Me)₆] | 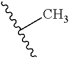 | 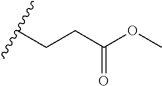 [SMILES: *CCC(=O)OC] |
| [(MeSn)₆O₆(O₂C—C₄H₅O₂)₆] | 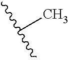 | 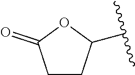 [SMILES: *C1CCC(=O)O1] |
| [(nBuSn)₆O₆(O₂C—C₄H₅O₂)₆] | 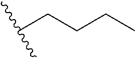 [SMILES: *CCCC] | 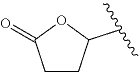 [SMILES: *C1CCC(=O)O1] |
| [(VinylSn)₆O₆(O₂C—C₄H₅O₂)₆] | 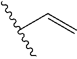 [SMILES: *C=C] | 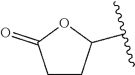 [SMILES: *C1CCC(=O)O1] |
| [(MeSn)₆O₆(O₂C—CO₂C₃H₅)₆] | 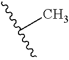 | 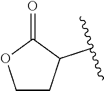 [SMILES: *C1CCOC1=O] |
| [(MeSn)₆O₆(O₂C-(E)-CH═CHCO₂Me)₆] | 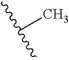 | 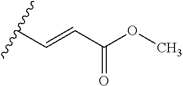 [SMILES: */C=C/C(=O)OC] |
| [(MeSn)₆O₆(O₂C-(E)-CH═CHCO₂iPr)₆] | 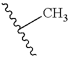 | 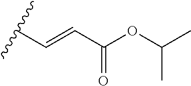 [SMILES: */C=C/C(=O)OC(C)C] |
| [(MeSn)₆O₆(O₂C-(E)-CH═CHCO₂tBu)₆] | 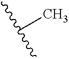 | 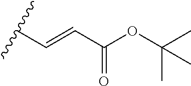 [SMILES: */C=C/C(=O)OC(C)(C)C] |
| [(MeSn)₆O₆(O₂C-(Z)-CH═CHCO₂Me)₆] | 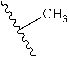 | 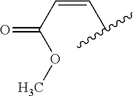 [SMILES: */C=C\C(=O)OC] |
| [(MeSn)₆O₆(O₂C—CH(O₂CCH₃)CH₃)₆] | 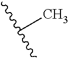 | 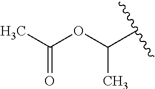 [SMILES: *C(C)OC(C)=O] |
| [(MeSn)₆O₆(O₂C—CHOCOC₆H₄)₆] | 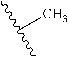 | 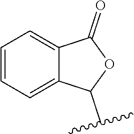 [SMILES: *C1OC(=O)c2ccccc21] |
| [(MeSn)₆O₆(O₂C-p-C₆H₄CO₂tBu)₆] | 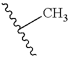 | 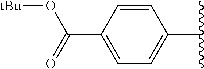 [SMILES: *c1ccc(C(=O)OC(C)(C)C)cc1] |
| [(MeSn)₆O₆(O₂C—CO₂Me)₆] | 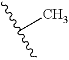 | 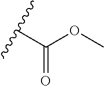 [SMILES: *C(=O)OC] |
| [(MeSn)₆O₆(O₂C—C₄(CH₃)₂H₃O₂)₆] | 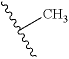 | 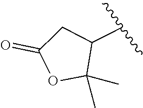 [SMILES: *C1CC(=O)OC1(C)C] |
| [(MeSn)₆O₆(O₂C—C₃H₄CO₂CH₃)₆] | 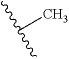 | 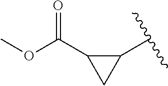 [SMILES: *C1CC1C(=O)OC] |
| [(MeSn)₆O₆(O₂C—C(CH₃)C₃H₄O₂)₆] | 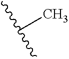 | 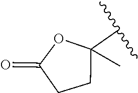 [SMILES: *C1(C)CCC(=O)O1] |

### Processes for Preparing Sn6-Oxo Clusters

As set forth above, the disclosed subject matter further includes processes for synthesizing the disclosed and claimed Sn6-oxo clusters.

In a typical synthesis, a solution of a monoorgano Sn starting material with a desired ligand(s), typically alkoxy, is prepared in an organic solvent or a mixture or solvent(s). Under stirring, water is added to (neat or as solution in an organic solvent or mixture of organic solvents). Stirring is continued and a carboxylic acid (1 eq. with respect to Sn) is either added as neat substance or as solution in an organic solvent or a solvent mixture to the reaction solution. The reaction solution is then further stirred, typically for several hours or overnight. The Sn6-oxo cluster can be isolated via removal of the solvent by filtration or evaporation, optionally at reduced pressure and/or elevated temperature. The reaction can be performed in a way that the resulting solution has an adjusted concentration so that it can directly be used for application purposes. The formation of Sn6 drum clusters is confirmed via ¹¹⁹Sn NMR of isolated material redissolved in a deuterated solvent or of concentrated reactions solutions with a capillary insert containing a deuterated solvent. Sn6 clusters containing MeSn units typically show NMR signals at −460±10 ppm. These signals can be used to detect successful cluster formation. Depending on the choice of carboxylic acids these signals can appear broadened due to, for example, chiral ligands and/or back-coordination of functional groups to tin atoms in the cluster.

In one aspect, the solvent is selected from toluene, THF, PGME, cyclohexanone, 2-heptanone, CPME, anisole and a mixture thereof. In one aspect, each addition step is performed at room temperature but can alternatively be performed at reduced or elevated temperatures in the range between the freezing and boiling points of the solvent(s). For instance, the addition of water may be performed at room temperature and the addition of the carboxylic acid may be performed at elevated temperatures or vice versa. The addition steps may also be performed at the same temperature. Thus, in one aspect, some or all of the steps of the process are conducted at a temperature of between about 0° C. to a temperature which is at or below the boiling point of the solvent(s) employed. In another aspect, some or all of the steps of the process are conducted at a temperature of between about 10° C. to about 60° C. In another aspect, some or all of the steps of the process are conducted at a temperature of between about 15° C. to about 30° C. In another aspect, some or all of the steps of the process are conducted at a temperature of between about 18° C. to about room temperature. In another aspect, all of the steps are performed at a temperature of between about room temperature and a temperature which is at or below the boiling point of the solvent(s) employed. In another aspect, all of the steps of the process are performed at room temperature.

In one aspect, the yield of the Sn6-oxo clusters from the process is about or above 80%. In another aspect, the yield of the Sn6-oxo clusters from the process is about or above 85%. In another aspect, the yield of the Sn6-oxo clusters from the process is about or above 90%. In another aspect, the yield of the Sn6-oxo clusters from the process is about or above 95%.

### Sn6-Oxo Cluster Formulations and Uses Thereof

In another aspect, the disclosed and claimed subject matter includes formulations that include (i) one or more of the disclosed and claimed Sn6-oxo clusters and (ii) one or more solvents suitable for use in a spin-coating process. In one embodiment, the formulation includes (i) two or more of the disclosed and claimed Sn6-oxo clusters and (ii) one or more solvents suitable for use in a spin-coating process.

In another aspect, the disclosed and claimed subject matter includes preparing the target compounds in a spin-coating solvent (mixture) at the desired concentration, circumventing the isolation of the material and direct formation of the spin-coatable formulation. In one aspect, such formulations are free of toluene.

In one embodiment, the one or more solvents suitable for use in a spin-coating process includes one or more of an alcohol, an ester, a ketone, a lactone, a diketone, a solvent with aromatic moieties, a solvent with a carboxylic acid, an amide and mixtures thereof.

In another embodiment, the one or more solvents suitable for use in a spin-coating process includes one or more of 1-methoxy-2-propanyl acetate (PGMEA), 1-methoxy-2-propanol (PGME), butyl acetate, amyl acetate, cyclohexyl acetate, 3-methoxybutyl acetate, methyl ethyl ketone, methyl amyl ketone, cyclohexanone, cyclopentanone, ethyl-3-ethoxy propanoate, methyl-3-ethoxy propanoate, methyl-3-methoxy propanoate, methyl acetoacetate, ethyl acetoacetate, diacetone alcohol, methyl pivalate, ethyl pivalate, propylene glycol monomethyl ether, propylene glycol monoethyl ether, propylene glycol monomethyl ether propanoate, propylene glycol monoethyl ether propanoate, ethylene glycol monomethyl ether, ethylene glycol monoethyl ether, diethylene glycol monomethyl ether, diethylene glycol monoethyl ether, 3-methyl-3-methoxybutanol, N-methylpyrrolidone, dimethyl sulfoxide, gamma-butyrolactone, gamma valerolactone, cyclopentyl methyl ether, propylene glycol methyl ether acetate, propylene glycol ethyl ether acetate, propylene glycol propyl ether acetate, methyl lactate, ethyl lactate, propyl lactate, tetramethylene sulfone, propylene glycol dimethyl ether, dipropylene glycol dimethyl ether, ethylene glycol dimethyl ether, diethylene glycol dimethyl ether, toluene, 2-heptanone, 1-hexanol, 4-methyl-2-pentanol and anisole. In a further aspect of this embodiment, the one or more solvents for use in a spin-coating process includes one or more of toluene, THF, cyclohexanone, PGME, PGMEA, anisole, 2-heptanone and 4-methyl-2-pentanol. In a further aspect of this embodiment, the one or more solvents for use in a spin-coating process includes one or more of THF, cyclohexanone, PGME, PGMEA, anisole, 2-heptanone and 4-methyl-2-pentanol. In one aspect, such formulations are free of toluene.

In another embodiment, the Sn6-oxo cluster formulations have a concentration of Sn clusters of about 1 mg/mL to about 1000 mg/mL. In another embodiment, the Sn6-oxo clusters can be formulated into solutions having a concentration of Sn clusters of about 1 mg/mL to about 100 mg/mL. In another embodiment, the Sn6-oxo clusters can be formulated into solutions having a concentration of Sn clusters of about 1 mg/mL to about 50 mg/mL. In another embodiment, the Sn6-oxo clusters can be formulated into solutions having a concentration of Sn clusters of about 10 mg/mL to about 50 mg/mL. In another embodiment, the Sn6-oxo cluster formulations have a concentration of Sn clusters of about 25 mg/mL to about 50 mg/mL. In another embodiment, the Sn6-oxo cluster formulations have a concentration of Sn clusters of about 50 mg/mL to about 100 mg/mL.

The disclosed and claimed subject matter further includes using the disclosed and claimed Sn6-oxo cluster formulations in EUV and ebeam processes. Such formulations are or can be used for patterning a radiation sensitive coating in a process that includes the steps of (i) forming a coating on a substrate surface with one or more of the disclosed and claimed Sn6-oxo cluster formulations, (ii) drying the coating to produce a dried layer; and (iii) irradiating at least a portion of the dried layer to form a latent image.

In one embodiment, the substrate of step (i) includes silicon. In one embodiment, the substrate of step (i) includes silicon and at least one additional material layer (i.e., a stack of materials) on top of which the material is deposited.

In one embodiment, the dried layer of step (ii) has a thickness of about 1 nm to about 500 nm. In one embodiment, the dried layer of step (ii) has a thickness of about 10 nm to about 100 nm. In one embodiment, the dried layer of step (ii) has a thickness of about 15 nm to about 50 nm.

In one embodiment, the irradiating of step (iii) includes exposing at least a portion of the dried layer to ionizing radiation. In one aspect of this embodiment, the ionizing radiation has a wavelength range of about 10 nm to about 365 nm. In one aspect of this embodiment, the ionizing radiation is generated via electron beams.

Method of photopatterning the materials: spincoating on a substrate at 500 rpm/5s then 800-5000 rpm for 15-120 s, exposing with e-beam at 2-100 keV for 1-10,000 μC or EUV (13.5 nm) through a mask, baking the exposed wafer for 0.5-20 minutes at 100-200° C., developing for 15-300 sec in organic solvent (mixtures). Solvents and mixtures thereof include, but are not limited to, 2-hetptanone, cyclohexanone, PGMEA, PGME, a mixture of anisole and PGMEA, a mixture of anisole and cyclohexanone and a mixture of anisole and 2-heptanone.

It will also be apparent to those skilled in the art that various modifications may be made in how the disclosed subject matter is practiced based on described aspects in the specification without departing from the spirit and scope of the disclosed subject matter disclosed herein.

### EXAMPLES

Reference will now be made to more specific embodiments of the present disclosure and experimental results that provide support for such embodiments. The examples are given below to more fully illustrate the disclosed subject matter and should not be construed as limiting the disclosed subject matter in any way.

It will be apparent to those skilled in the art that various modifications and variations can be made in the disclosed subject matter and specific examples provided herein without departing from the spirit or scope of the disclosed subject matter. Thus, it is intended that the disclosed subject matter, including the descriptions provided by the following examples, covers the modifications and variations of the disclosed subject matter that come within the scope of any claims and their equivalents.

### Materials and Methods

The disclosed and claimed processes utilizes commercially available materials (e.g., THF, PGME, cyclohexanone, toluene, acetic acid, 5-oxotetrahydrofuran-2-carboxylic acid (CAS 4344-84-7), mono-Methyl fumarate (CAS 2756-87-8), monomethyl maleate (CAS 3052-50-4), Monomethyl hydrogen malonate (CAS 16695-14-0), mono-methyl hydrogen succinate (CAS 3878-55-5), 4-(tert-butoxycarbonyl)benzoic acid (CAS 20576-82-3), 2-acetoxy propionic acid (CAS 535-17-1), 2-methoxy-2-oxoacetic acid (CAS 600-23-7), 2,2-dimethyl-5-oxooxolane-3-carboxylic acid (CAS 79-91-4), 2-(methoxycarbonyl)cyclopropane carboxylic acid (CAS 13279-88-4), 2-methyl-5-oxo-tetrahydro-2-furan carboxylic acid (CAS 57651-41-9), CDCl₃, C₆D₆, THF-d₈). Tetrahydro-2-oxo-3-furancarboxylic acid (CAS 4360-91-2) was prepared according to a literature procedure. See Zhen et al., Org. Lett., 21, 890-894 (2019). RSn(OtAmyl)₃ compounds were prepared according to (modified) literature procedures. See F. Banse et al., Inorg. Chem, 34, 6371 (1995). [(nBuSn)₆O₆(O₂C—CH₃)₆] was prepared according to modified literature procedures. See Chandrasekhar et al., Inorg. Chem., 26, 1050 (1987). VinylSn(C≡C-nC₃H₇)₃ was prepared according to a modified literature procedure. See Jaumier et al., Chem. Commun., 369 (1989).

### Example 1: Preparation of [(MeSn)₆O₆(O₂C(C₆H₄)CO₂C(CH₃)₃)₆]

MeSn(OtAmyl)₃ (948 mg, 2.4 mmol) was weighed into a 50 mL crimp vial inside a glovebox, equipped with a stir bar, and 20 mL of THE is added. The vial was sealed and transferred outside, where water (0.130 ml; 7.20 mmol; 3.00 eq.) was added. Upon addition, a white precipitate forms that did not redissolve with continued stirring. 4-(tert-Butoxycarbonyl)benzoic acid

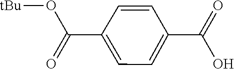 [SMILES: CC(C)(C)OC(=O)c1ccc(C(=O)O)cc1]

(533.4 mg; 2.40 mmol; 1.00 eq.) was dissolved in 5 mL of THE and added via syringe and stirring was continued. The white precipitate slowly redissolved, affording an almost clear solution after 1 hour that turned completely clear overnight. All volatiles were removed on a rotary evaporator, affording 824 mg (93%) of the product as an off-white powder.

The substance was identified as [(MeSn)₆O₆(O₂C(C₆H₄)CO₂C(CH₃)₃)₆] via ¹H NMR and ¹¹⁹Sn NMR (CDCl₃). It shows a signal at −460 ppm in the ¹¹⁹Sn NMR.

### Example 2: Preparation of [(MeSn)₆O₆(O₂C—CH₂CO₂Me)₆]

MeSn(OtAmyl)₃ (591 mg, 1.5 mmol) was weighed into a 50 mL crimp vial inside a glovebox and equipped with a stir bar. The vial was sealed and transferred outside, where 9 mL of cyclohexanone and 9 mL of PGME were added. Afterwards, water (81 μL; 4.5 mmol; 3.00 eq.) was added, leading to the formation of a white precipitate that did not redissolve with continued stirring. Mono-Methyl hydrogen malonate

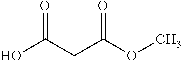

(184 mg; 1.5 mmol; 1.00 eq.) was dissolved in 2 mL of a 1:1 cyclohexanone:PGME mixture. The resulting solution was added to the crimp-vial via syringe and stirring was continued. The white precipitate quickly redissolved after acid addition. The solution was filtered through a paper filter and used for application testing as is. 5 mL of the solution was concentrated to approximately 1 mL on a rotary evaporator and then used for NMR spectroscopy.

The substance was identified as [(MeSn)₆O₆(O₂C—CH₂CO₂Me)₆] via ¹¹⁹Sn NMR. It shows a signal at −462 ppm in the ¹¹⁹Sn NMR.

### Example 3: Preparation of [(MeSn)₆O₆(O₂C—C₂H₄CO₂Me)₆]

MeSn(OtAmyl)₃ (562 mg, 1.4 mmol) was weighed into a 50 mL crimp vial inside a glovebox and equipped with a stir bar. The vial was sealed and transferred outside, where 9 mL of cyclohexanone and 9 mL of PGME were added. Afterwards, water (77 μL; 4.3 mmol; 3.00 eq.) was added, leading to the formation of a white precipitate that did not redissolve with continued stirring. Mono-Methyl hydrogen succinate

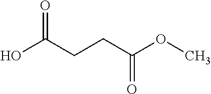

(198 mg; 1.4 mmol; 1.00 eq.) was dissolved in 2 mL of a 1:1 cyclohexanone:PGME mixture. The resulting solution was added to the crimp-vial via syringe and stirring was continued. The white precipitate quickly redissolved after acid addition. The solution was filtered through a paper filter and used for application testing as is. 5 mL of the solution was concentrated to approximately 1 mL on a rotary evaporator and then used for NMR spectroscopy.

The substance was identified as [(MeSn)₆O₆(O₂C—C₂H₄CO₂Me)₆] via ¹¹⁹Sn NMR. It shows a signal at −465 ppm in the ¹¹⁹Sn NMR.

### Example 4: Preparation of [(MeSn)₆O₆(O₂C-(E)-CH═CHCO₂Me)₆]

MeSn(OtAmyl)₃ (565 mg, 1.4 mmol) was weighed into a 50 mL crimp vial inside a glovebox and equipped with a stir bar. The vial was sealed and transferred outside, where 9 mL of cyclohexanone and 9 mL of PGME were added. Afterwards, water (77 μL; 4.3 mmol; 3.00 eq.) was added, leading to the formation of a white precipitate that did not redissolve with continued stirring. Monomethyl fumarate

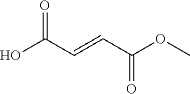

(192 mg; 1.4 mmol; 1.00 eq.) was dissolved in 2 mL of a 1:1 cyclohexanone:PGME mixture. The resulting solution was added to the crimp-vial via syringe and stirring was continued. The white precipitate quickly redissolved after acid addition. The solution was filtered through a paper filter and used for application testing as is. 4 mL of the solution was concentrated to approximately 1 mL on a rotary evaporator and then used for NMR spectroscopy.

The substance was identified as [(MeSn)₆O₆(O₂C-(E)-CH═CHCO₂Me)₆ via ¹¹⁹Sn NMR. It shows a signal at −458 ppm in the ¹¹⁹Sn NMR.

### Example 5: Preparation of [(MeSn)₆O₆(O₂C—(Z)—CH═CHCO₂Me)₆]

MeSn(OtAmyl)₃ (848 mg, 2.2 mmol) was weighed into a 50 mL crimp vial inside a glovebox and equipped with a stir bar. The vial was sealed and transferred outside, where 14 mL of cyclohexanone and 14 mL of PGME were added. Afterwards, water (116 μL; 6.6 mmol; 3.00 eq.) was added, leading to the formation of a white precipitate that did not redissolve with continued stirring. Monomethyl maleate

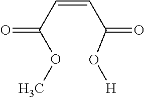

(294 mg; 2.2 mmol; 1.00 eq.) was dissolved in 2 mL of a 1:1 cyclohexanone:PGME mixture. The resulting solution was added to the crimp-vial via syringe and stirring was continued. The white precipitate quickly redissolved after acid addition. The solution was filtered through a paper filter and used for application testing as is. 5 mL of the solution was concentrated to approximately 1 mL on a rotary evaporator and then used for NMR spectroscopy.

The substance was identified as [(MeSn)₆O₆(O₂C—(Z)—CH═CHCO₂Me)₆] via ¹¹⁹Sn NMR. It shows a signal at −460 ppm in the ¹¹⁹Sn NMR.

### Example 6: Preparation of [(MeSn)₆O₆(O₂C—CH(O₂CCH₃)CH₃)₆]

MeSn(OtAmyl)₃ (1.12 g, 2.8 mmol) was weighed into a 50 mL crimp vial inside a glovebox and equipped with a stir bar. The vial was sealed and transferred outside, where 19 mL of cyclohexanone and 19 mL of PGME were added. Afterwards, water (154 μL, 8.4 mmol; 3.00 eq.) was added, leading to the formation of a white precipitate that did not redissolve with continued stirring. 2-Acetoxypropionic acid

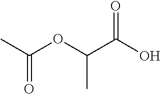

(383 mg, 2.8 mmol; 1.00 eq.) was dissolved in 2 mL of a 1:1 cyclohexanone:PGME mixture. The resulting solution was added to the crimp-vial via syringe and stirring was continued. The white precipitate quickly redissolved after acid addition. The solution was filtered through a paper filter and used for application testing as is. 10 mL of the solution was concentrated to approximately 1 mL on a rotary evaporator and then used for NMR spectroscopy.

The substance was identified as [(MeSn)₆O₆(O₂C—CH(O₂CCH₃)CH₃)₆] via ¹¹⁹Sn NMR (CDCl₃). It shows a signal at −459 ppm in the ¹¹⁹Sn NMR.

### Example 7: Preparation of [(nBuSn)₆O₆(O₂CC₄H₅O₂)₆]

nBuSn(OtAmyl)₃ (3 g, 6.86 mmol) was weighed into a 50 mL crimp vial inside a glovebox, equipped with a stir bar, and 28 mL of THF was added. The vial was sealed and transferred outside, where water (0.37 ml; 0.02 mmol; 3.00 eq.) was added. Upon addition a white precipitate formed that slowly redissolved with continued stirring. 5-Oxotetrahydrofuran-2-carboxylic acid

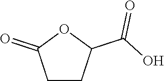

(0.89 g; 6.86 mmol) was dissolved in 5 mL of THE and added via syringe and stirring was continued overnight. All volatiles were removed on a rotary evaporator, affording 2.2 g (97%) of the product as an off-white powder.

The substance was identified as (nBuSn)₆O₆(O₂CC₄H₅O₂)₆ via ¹H NMR and ¹¹⁹Sn-NMR (CDCl₃). It shows a signal at −476 ppm in the ¹¹⁹Sn NMR.

### Example 8: Preparation of [(MeSn)₆O₆(O₂CC₄H₅O₂)₆]

MeSn(OtAmyl)₃ (948 mg, 2.4 mmol) was weighed into a 50 mL crimp vial inside a glovebox, equipped with a stir bar, and 15 mL of THF was added. The vial was sealed and transferred outside, where water (0.13 ml; 7.2 mmol; 3.00 eq.) was added. Upon addition a white precipitate formed that does not redissolve with continued stirring. 5-Oxotetrahydrofuran-2-carboxylic acid

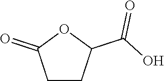

(312 g; 2.4 mmol) was dissolved in 5 mL of THF and added via syringe and stirring was continued overnight. All volatiles were removed on a rotary evaporator, affording 0.62 g (93%) of the product as an off-white powder.

The substance was identified as [(MeSn)₆O₆(O₂CC₄H₅O₂)₆] via ¹H NMR and ¹¹⁹Sn-NMR (THF-d₈). It shows a signal at −458 ppm in the ¹¹⁹Sn NMR.

### Example 9: Preparation of [(MeSn)₆O₆(O₂C—CO₂C₃H₅)₆]

MeSn(OtAmyl)₃ (565 mg, 1.4 mmol) was weighed into a 50 mL crimp vial inside a glovebox and equipped with a stir bar. The vial was sealed and transferred outside, where 9 mL of cyclohexanone and 9 mL of PGME were added. Afterwards, water (77 μL; 4.3 mmol; 3.00 eq.) was added, leading to the formation of a white precipitate that did not redissolve with continued stirring. Tetrahydro-2-oxo-3-furancarboxylic acid

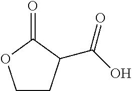

(186 mg; 1.4 mmol; 1.00 eq.) was dissolved in 2 mL of a 1:1 cyclohexanone:PGME mixture. The resulting solution was added to the crimp-vial via syringe and stirring was continued. The white precipitate quickly redissolved after acid addition. The solution was filtered through a paper filter and used for application testing as is. A 5 mL aliquot was taken, and all volatiles removed on a rotavap. The resulting white powder was redissolved in CDCl₃ and the sample used for NMR spectroscopy. In addition, 5 mL of the solution was concentrated to approximately 1 mL on a rotary evaporator and then used for NMR spectroscopy.

The substance was identified as [(MeSn)₆O₆(O₂C—CO₂C₃H₅)₆] via ¹¹⁹Sn NMR of the isolated solid and the concentrated solution. It shows a signal at −457 ppm in the ¹¹⁹Sn NMR.

### Example 10: Preparation of [(MeSn)₆O₆(O₂C—CO₂CH₃)₆]

MeSn(OtBu)₃ (557 mg, 1.6 mmol) was weighed into a 50 mL crimp vial inside a glovebox and equipped with a stir bar. The vial was sealed and transferred outside, where 9 mL of cyclohexanone and 9 mL of PGME were added. Afterwards, water (85 μL; 4.8 mmol; 3.00 eq.) was added, leading to the formation of a white precipitate that did not redissolve with continued stirring. 2-methoxy-2-oxoacetic acid

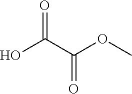

(168 mg; 1.6 mmol; 1.00 eq.) was dissolved in 2 mL of a 1:1 cyclohexanone:PGME mixture. The resulting solution was added to the crimp-vial via syringe and stirring was continued. The white precipitate quickly redissolved after acid addition. The solution was filtered through a paper filter and used for application testing as is. 5 mL of the solution were concentrated to approximately 1 mL on a rotary evaporator and then used for NMR spectroscopy.

The substance was identified as [(MeSn)₆O₆(O₂C—CO₂CH₃)₆] via ¹¹⁹Sn NMR of the concentrated solution. It shows a signal at −450 ppm in the ¹¹⁹Sn NMR.

### Example 11: Preparation of [(MeSn)₆O₆(O₂C—C₄(CH₃)₂H₃O₂)₆]

MeSn(OtBu)₃ (689 mg, 1.9 mmol) was weighed into a 50 mL crimp vial inside a glovebox and equipped with a stir bar. The vial was sealed and transferred outside, where 13 mL of cyclohexanone and 13 mL of PGME were added. Afterwards, water (106 μL; 5.8 mmol; 3.00 eq.) was added, leading to the formation of a white precipitate that did not redissolve with continued stirring. 2,2-dimethyl-5-oxooxolane-3-carboxylic acid

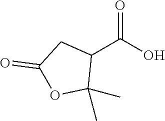

(325 mg; 1.9 mmol; 1.00 eq.) was dissolved in 4 mL of a 1:1 cyclohexanone:PGME mixture. The resulting solution was added to the crimp-vial via syringe and stirring was continued. The white precipitate quickly redissolved after acid addition. The solution was filtered through a paper filter and used for application testing as is. 5 mL of the solution were concentrated to approximately 1 mL on a rotary evaporator and then used for NMR spectroscopy.

The substance was identified as [(MeSn)₆O₆(O₂C— C₄(CH₃)₂H₃O₂)₆] via ¹¹⁹Sn NMR of the concentrated solution. It shows a signal at −459 ppm in the ¹¹⁹Sn NMR.

### Example 12: Preparation of [(MeSn)₆O₆(O₂C—C₃H₄CO₂CH₃)₆]

MeSn(OtAmyl)₃ (808 mg, 2.0 mmol) was weighed into a 50 mL crimp vial inside a glovebox and equipped with a stir bar. The vial was sealed and transferred outside, where 26 mL of cyclohexanone were added. Afterwards, water (110 μL; 6.1 mmol; 3.00 eq.) was added, leading to the formation of a white precipitate that did not redissolve with continued stirring. 2-(Methoxycarbonyl)cyclopropane carboxylic acid

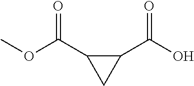

(301 mg; 2.0 mmol; 1.00 eq.) was dissolved in 4 mL of cyclohexanone. The resulting solution was added to the crimp-vial via syringe and stirring was continued. The white precipitate quickly redissolved after acid addition. The solution was filtered through a paper filter and used for application testing as is. 5 mL of the solution were concentrated to approximately 1 mL on a rotary evaporator and then used for NMR spectroscopy.

The substance was identified as [(MeSn)₆O₆(O₂C—C₃H₄CO₂CH₃)₆] via ¹¹⁹Sn NMR of the concentrated solution. It shows a signal at −464 ppm in the ¹¹⁹Sn NMR.

### Example 13: Preparation of [(MeSn)₆O₆(O₂C—C(CH₃)C₃H₄O₂)₆]

MeSn(OtBu)₃ (716 mg, 2.0 mmol) was weighed into a 50 mL crimp vial inside a glovebox and equipped with a stir bar. The vial was sealed and transferred outside, where 28 mL of cyclohexanone were added. Afterwards, water (110 μL; 6.1 mmol; 3.00 eq.) was added, leading to the formation of a white precipitate that did not redissolve with continued stirring. 2-methyl-5-oxo-tetrahydro-2-furan carboxylic acid

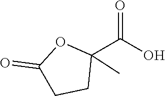

(292 mg; 2.0 mmol; 1.00 eq.) was dissolved in 2 mL of cyclohexanone. The resulting solution was added to the crimp-vial via syringe and stirring was continued. The white precipitate slowly redissolves after acid addition. The solution was filtered through a paper filter and used for application testing as is. 5 mL of the solution were concentrated to approximately 1 mL on a rotary evaporator and then used for NMR spectroscopy.

The substance was identified as [(MeSn)₆O₆(O₂C—C(CH₃)C₃H₄O₂)₆] via ¹¹⁹Sn NMR of the concentrated solution. It shows a signal at −455 ppm in the ¹¹⁹Sn NMR.

### Example 14: Preparation of [(VinylSn)₆O₆(O₂C—C₄H₅O₂)₆]

VinylSn(C≡C-nC₃H₇)₃ (595 mg, 1.7 mmol) was weighed into a 50 mL crimp vial inside a glovebox and equipped with a stir bar. The vial was sealed and transferred outside, where 35 mL of cyclohexanone were added. Afterwards, water (93 μL; 5.2 mmol; 3.00 eq.) was added, affording a clear solution. 5-Oxo-tetrahydro-2-furan carboxylic acid

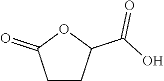

(235 mg; 1.7 mmol; 1.00 eq.) was dissolved in 5 mL of cyclohexanone. The resulting solution was added to the crimp-vial via syringe and stirring was continued. The white precipitate slowly redissolves after acid addition. The solution was filtered through a 0.2 μm syringe filter and used for application testing as is. 5 mL of the solution were concentrated to approximately 1 mL on a rotary evaporator and then used for NMR spectroscopy.

The substance was identified as [(vinylSn)₆O₆(O₂C—C₄H₅O₂)₆] via ¹¹⁹Sn NMR of the concentrated solution. It shows a signal at −532 ppm in the ¹¹⁹Sn NMR.

### Comparative Study 1: Exemplary Processing for Formulations and Electron Beam Exposures

If a solid material was to be deposited, a solution was prepared by dissolving the material in an appropriate solvent (mixture) to prepare a solution with a target concentration of 20 g/L. If a reaction solution was used as a formulation, this solution was prepared in such a way that the product concentration was 20 g/L.

Before coating a formulation, it was filtered through a 0.2 μm syringe filter. In the following step, an Si wafer was spin coated with a spin speed depending on viscosity of the formulation to get a film thickness of 25 to 30 nm. After a soft bake at 100° C. for 2 minutes, small fields of 10 μm×40 μm were exposed with electron beam with dose levels from 5000 or 500 μC/cm² to 10 or 1 μC/cm² (Acceleration voltage 30 kV). After a post exposure bake at 120° C. for 2 minutes, the wafer was developed for 2 minutes in a bath of 2-heptanone and rinsed with 2-heptanone for 15 seconds. Finally, the wafer was dried in an N₂ stream. The structures were then determined via profilometry and peak height to dose are translated into fitted dose level curves. The D₅₀ value is defined as the exposure dose at which 50% of the film thickness of the fully cured material is retained after development. This value is used as a performance indicator for the sensitivity of a given material. The results from the e-beam experiments are summarized in Table 3.

TABLE 3

| | |
|---|---|
| Resist Material | D₅₀ (μC/cm²) |

| | | |
|---|---|---|
| 1 | [(MeSn)₆O₆(O₂C—CH═CHCO₂Me)₆] | 51 |
| 2 | [(MeSn)₆O₆(O₂C—CH₂CO₂Me)₆] | 101 |
| 3 | [(MeSn)₆O₆(O₂C—C₄H₅O₂)₆] | 76 |
| 4 | [(nBuSn)₆O₆(O₂C—C₄H₅O₂)₆] | 179 |
| 5 | [(nBuSn)₆O₆(O₂C—CH₃)₆] (reference) | 245 |

### Comparative Study 1: EUV Exposures

For [(nBuSn)₆O₆(O₂CCH₃)₆] and [(MeSn)₆O₆(O₂CC₄H₅O₂)₆] clusters dose curves were recorded at the Paul Scherrer Institute with EUV radiation. Wafers were prepared and processed the same way as described above. Only radiation was shifted from e-beam to EUV radiation. The lactone containing Sn6 drum cluster [(MeSn)₆O₆(O₂CC₄H₅O₂)₆] shows higher sensitivity than the literature reference [(nBuSn)₆O₆(O₂CCH₃)₆] under EUV exposure. The results are summarized in Table 4.

TABLE 4

| | |
|---|---|
| Resist Material | D₅₀ (mJ/cm²) |

| | | |
|---|---|---|
| 1 | [(MeSn)₆O₆(O₂CC₄H₅O₂)₆] | 15.47 |
| 2 | [(nBuSn)₆O₆(O₂CCH₃)₆] (reference) | 39.94 |

Although the invention has been described and illustrated with a certain degree of particularity, it is understood that the disclosure has been made only by way of example, and that numerous changes in the conditions and order of steps can be resorted to by those skilled in the art without departing from the spirit and scope of the invention.

1. A tin compound of the formula [(R^{a}Sn)₆O₆(O₂C—R^{b})₆], wherein
(A) R^{a} is selected from the group of an unsubstituted linear C₁-C₁₀ alkyl group, a linear C₁-C₆ alkyl group substituted with a halogen, a linear C₁-C₆ alkyl group substituted with an amino group, a linear C₁-C₆ alkyl group substituted with a C₅-C₆ unsubstituted aromatic group, an unsubstituted branched C₃-C₁₀ alkyl group, a branched C₃-C₁₀ alkyl group substituted with a halogen, a C₁-C₁₀ heteroalkylene, a branched C₃-C₁₀ alkyl group substituted with an unsubstituted amine, a substituted amine, —Si(CH₃)₃, a benzyl group, a C₃-C₈ unsubstituted cyclic alkyl group, a C₃-C₈ cyclic alkyl group substituted with a halogen, a C₃-C₈ cyclic alkyl group substituted with an amino group, a C₄-C₈ unsubstituted aromatic group, a C₄-C₈ aromatic group substituted with a halogen, a C₄-C₈ aromatic group substituted with an amino group, a C₃-C₁₀ heterocyclic group, a C₂-C₁₀ alkenyl group and a C₃-C₁₀ alkynyl group; and
(B) R^{b} is a carboxylic acid moiety group selected from the group of
(ii) formula (2): 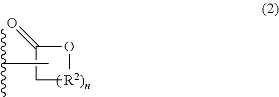
wherein (i) n=1-5, (ii) each R² is individually one of an oxygen, an unsubstituted methylene group or a methylene group substituted with one or two C₁-C₄ alkyl groups and (iii) formula (2) is free of peroxide groups; and
(iii) formula (3): 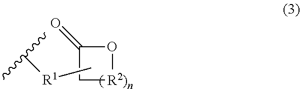
wherein (i) R¹ is an unsubstituted linear C₁-C₆ alkylene group, an unsubstituted branched C₃-C₆ alkylene group, an unsubstituted linear C₂-C₆ alkenylene group, an unsubstituted branched C₃-C₆ alkenylene group, an unsubstituted linear C₂-C₆ alkynylene group, an unsubstituted branched C₄-C₆ alkynylene group or a C₃-C₈ unsubstituted cyclic alkylene group, (ii) n=1-5, (iii) each R² is individually one of an oxygen, an unsubstituted methylene group or a methylene group substituted with one or two C₁-C₄ alkyl groups and (iv) formula (3) is free of peroxide groups.

2. The compound of claim 1, wherein R^{a} is selected from the group consisting of an unsubstituted linear C₁-C₄ alkyl group, an unsubstituted branched C₃-C₄ alkyl group, a C₂-C₆ alkenyl group and a C₅-C₆ unsubstituted aromatic group.

3. The compound of claim 1, wherein R^{a} is selected from the group consisting of a —CH₃ group, a —CH₂CH₃ group, a —CH(CH₃)₂ group, a —C(CH₃)₃ group, a —CH═CH₂ group, a —CH₂CH═CH₂ group, a —CH₂CH₂CH═CH₂ group, a —CH₂CH₂CH₂CH₃ group, a —C₆H₅ group and a —CH₂—C₆H₅ group.

4-49. (canceled)

50. The compound of claim 1, wherein R^{b} is a carboxylic acid moiety of formula (2):

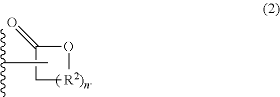

51-59. (canceled)

60. The compound of claim 1, wherein R^{b} is a carboxylic acid moiety of formula (3):

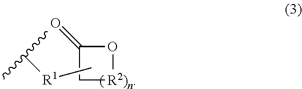

61-65. (canceled)

66. The compound of claim 1, wherein R^{b} is a carboxylic acid moiety of formula (3) wherein R¹ is an unsubstituted linear C₁-C₆ alkylene group.

67. The compound of claim 1, wherein R^{b} is a carboxylic acid moiety of formula (3) wherein R¹ is an unsubstituted branched C₃-C₆ alkylene group.

68-75. (canceled)

76. The compound of claim 1, wherein R^{b} is a carboxylic acid moiety of formula (3) wherein R¹ is an unsubstituted linear C₂-C₆ alkenylene group.

77. The compound of claim 1, wherein R^{b} is a carboxylic acid moiety of formula (3) wherein R¹ is an unsubstituted branched C₃-C₆ alkenylene group.

78. The compound of claim 1, wherein R^{b} is a carboxylic acid moiety of formula (3) wherein R¹ is an unsubstituted linear C₂-C₆ alkynylene group.

79. The compound of claim 1, wherein R^{b} is a carboxylic acid moiety of formula (3) wherein R¹ is an unsubstituted branched C₄-C₆ alkynylene group.

80. The compound of claim 1, wherein R^{b} is a carboxylic acid moiety of formula (3) wherein R¹ is a C₃-C₈ unsubstituted cyclic alkylene group.

81-142. (canceled)

143. The compound of claim 1, wherein R^{b} is a carboxylic acid moiety group derived from one or more of the following carboxylic acids:

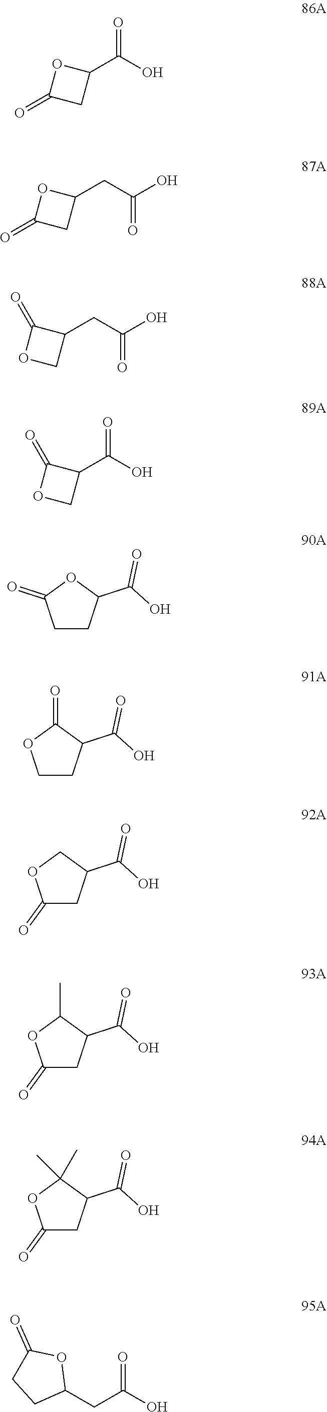

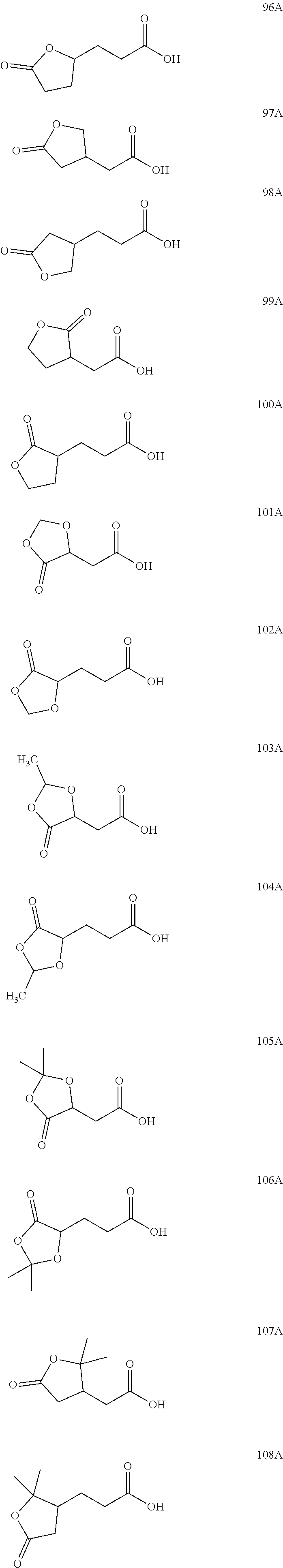

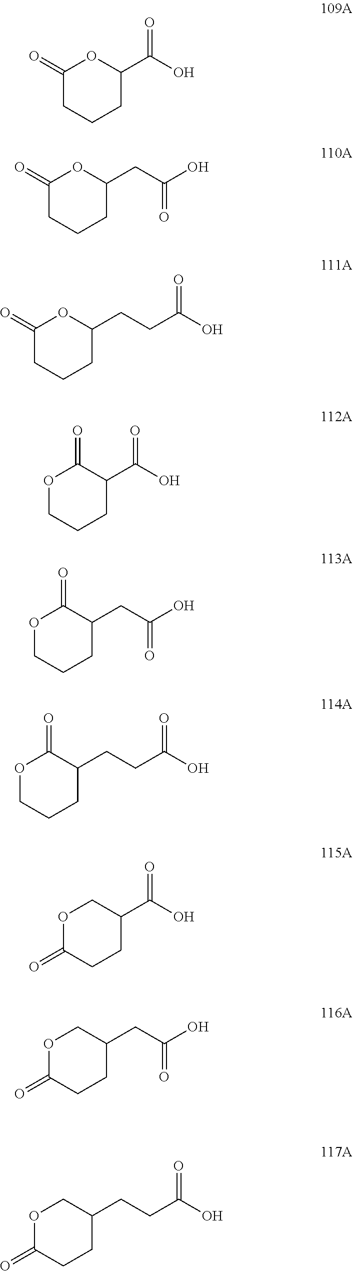

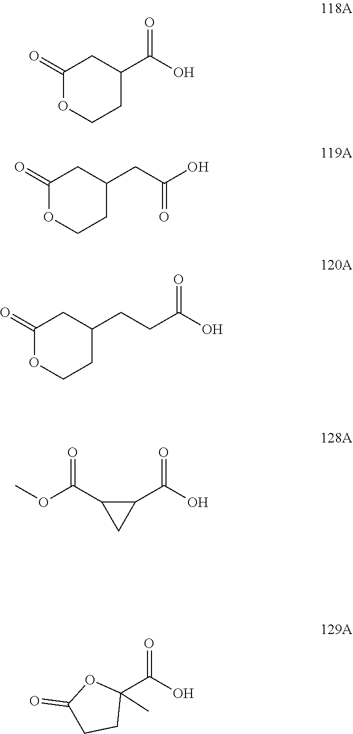

144-152. (canceled)

153. The compound of claim 143, wherein R^{b} is a carboxylic acid moiety group derived from carboxylic acid structure 90A.

154. The compound of claim 143, wherein R^{b} is a carboxylic acid moiety group derived from carboxylic acid structure 91A.

155. The compound of claim 143, wherein R^{b} is a carboxylic acid moiety group derived from carboxylic acid structure 92A.

156. The compound of claim 143, wherein R^{b} is a carboxylic acid moiety group derived from carboxylic acid structure 94A.

157. The compound of claim 143, wherein R^{b} is a carboxylic acid moiety group derived from carboxylic acid structure 101A.

158. The compound of claim 143, wherein R^{b} is a carboxylic acid moiety group derived from carboxylic acid structure 103A.

159. The compound of claim 143, wherein R^{b} is a carboxylic acid moiety group derived from carboxylic acid structure 105A.

160. A formulation comprising (i) a compound of claim 1 and (ii) one or more solvents suitable for use in a spin-coating process.

161-166. (canceled)

167. A process for patterning a radiation sensitive coating comprising:
(i) forming a coating on a substrate surface with a formulation comprising one or more compounds of claim 1;
(ii) drying the coating to produce a dried layer; and
(iii) irradiating at least a portion of the dried layer to form a latent image.

168-175. (canceled)
